(19) United States
(12) Patent Application Publication
(10) Pub. No.: US 2023/0215808 A1
(43) Pub. Date: Jul. 6, 2023

(54) SEMICONDUCTOR PACKAGE WITH INTEGRATED CIRCUIT CHIP COUPLERS

(71) Applicant: Taiwan Semiconductor Manufacturing Co., Ltd., Hsinchu (TW)

(72) Inventor: Jen-Yuan CHANG, Hsinchu City 300 (TW)

(73) Assignee: Taiwan Semiconductor Manufacturing Co., Ltd., Hsinchu (TW)

(21) Appl. No.: 17/858,971

(22) Filed: Jul. 6, 2022

Related U.S. Application Data
(60) Provisional application No. 63/295,331, filed on Dec. 30, 2021.

(51) Int. Cl. H01L 23/538; H01L 25/065; H01L 25/16; H01L 23/498; H01L 23/522; H01L 21/48

(52) U.S. Cl. CPC H01L 23/5386; H01L 25/0652; H01L 25/167; H01L 23/49816; H01L 23/49833; H01L 23/49838; H01L 23/5381; H01L 23/5385; H01L 23/5223; H01L 23/5225; H01L 21/486; H01L 24/16

(57) ABSTRACT

An integrated circuit (IC) chip package and a method of fabricating the same are disclosed. The IC chip package includes first and second interconnect substrates on a same surface level, first and second integrated circuit (IC) chips disposed on the first and second interconnect substrates, respectively, an IC chip coupler disposed on the first and second interconnect substrates and configured to provide a signal transmission path between the first and second IC chips, and a redistribution structure disposed on the first and second IC chips and the IC chip coupler. The IC chip coupler includes a first coupler region that overlaps with the first interconnect substrate, a second coupler region that overlaps with the second interconnect substrate, a third coupler region that overlaps with a space between the first and second interconnect substrates, and an interconnect structure with conductive lines and conductive vias.

### CROSS-REFERENCE TO RELATED APPLICATIONS

This application claims the benefit of U.S. Provisional Patent Application No. 63/295,331, titled “Semiconductor structure with linkage chip,” filed on Dec. 30, 2021, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around (GAA) FETs in integrated circuit (IC) chips. Such scaling down has increased the complexity of manufacturing the IC chips and the complexity of packaging the manufactured IC chips.

### BRIEF DESCRIPTION OF THE DRAWINGS

Aspects of this disclosure are best understood from the following detailed description when read with the accompanying figures.

FIG. 1A-1F illustrate cross-sectional and top-down views of an IC chip package with an IC chip coupler, in accordance with some embodiments.

FIG. 2A-2F illustrate cross-sectional and top-down views of another IC chip package with an IC chip coupler, in accordance with some embodiments.

FIGS. 3A-3E and 3G-3K illustrate different cross-sectional views of an IC chip coupler, in accordance with some embodiments.

FIG. 3F illustrate a top-down view of an IC chip coupler, in accordance with some embodiments.

FIGS. 4A-4C illustrate isometric and cross-sectional views of a device layer in an IC chip coupler, in accordance with some embodiments.

FIG. 5 is a flow diagram of a method for fabricating an IC chip package with an IC chip coupler, in accordance with some embodiments.

FIGS. 6-13 illustrate cross-sectional views of an IC chip package with an IC chip coupler at various stages of its fabrication process, in accordance with some embodiments.

FIG. 14 is a flow diagram of a method for fabricating another IC chip package with an IC chip coupler, in accordance with some embodiments.

FIGS. 15-24 illustrate cross-sectional views of another IC chip package with an IC chip coupler at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

An IC chip can include a compilation of layers with different functionality, such as interconnect structures, power distribution network, logic chips, memory chips, radio frequency (RF) chips, and the like. An IC chip package (also referred to as “semiconductor package”) can include multiple IC chips disposed on and electrically connected to different interconnect substrates, such as interposer structures, which can be disposed on and electrically connected to a package substrate. The interconnect substrates and the package substrate can provide electrical connections (also referred to as “signal transmission paths” or “metal routings”) between IC chips on the same interconnect substrates and/or between IC chips on different interconnect substrates. Electrical signals from IC chips on one interconnect substrate can be transmitted to IC chips on another interconnect substrate through the package substrate. However, the increasing demand for high-speed IC chip packages increases the challenges of designing and fabricating high-speed interconnections between IC chips on different interconnect substrates.

The present disclosure provides example structures of IC chip packages with IC chip couplers and example methods of fabricating the same to reduce the signal transmission path lengths between the IC chips on different interconnect substrates. In some embodiments, an IC chip coupler can be disposed on and electrically connected to two or more interconnect structures and can electrically connect the IC chips on different interconnect substrates. In some embodiments, electrical signals between the IC chips on different interconnect substrates can be transmitted through the IC chip coupler and the different interconnect substrates without passing through the package substrate. As a result, the signal transmission path lengths between the IC chips on different interconnect substrates can be reduced, thus decreasing the signal transmission path resistance and increasing the signal transmission speed and bandwidth of the IC chip package.

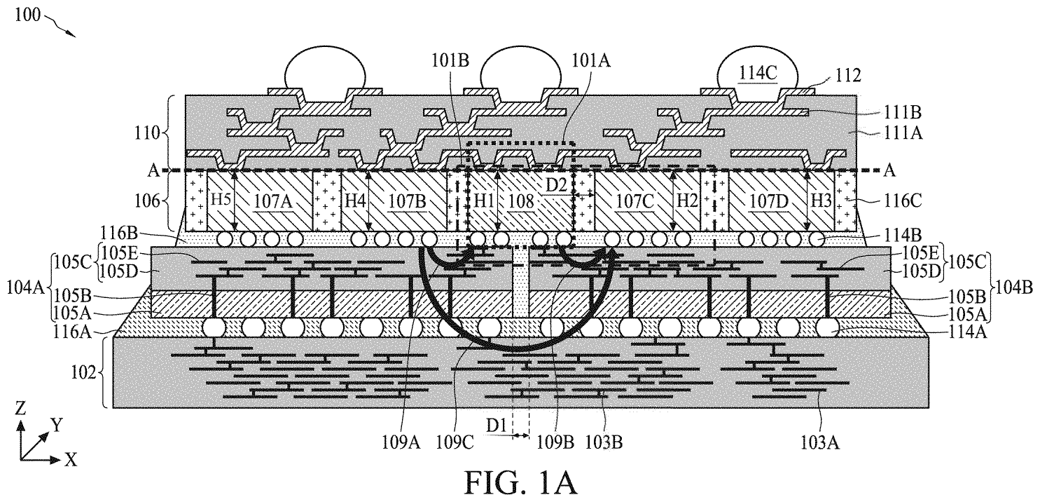

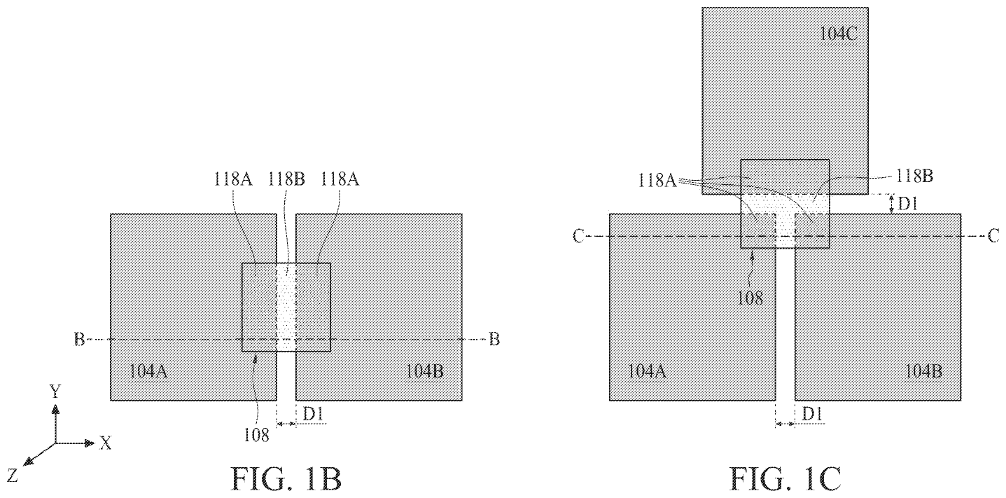

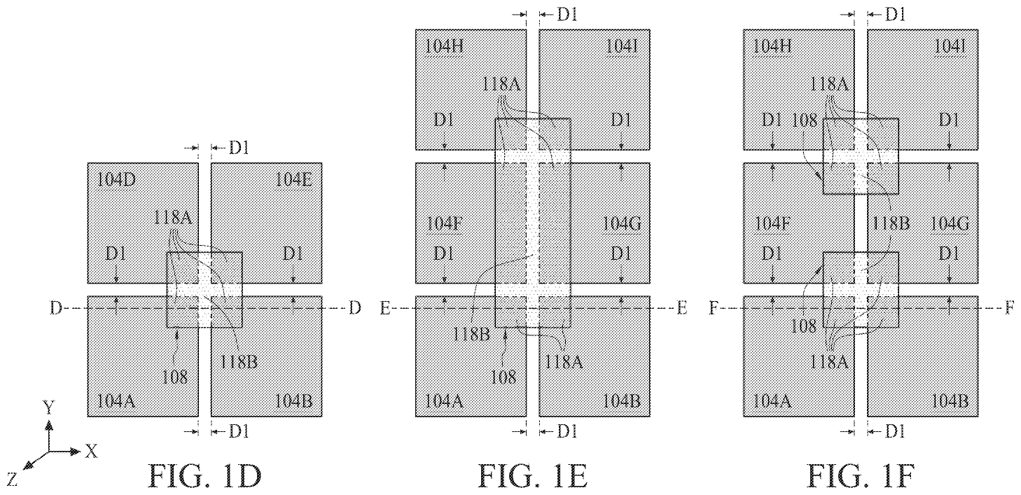

FIG. 1A illustrates a cross-sectional view of an IC chip package 100, according to some embodiments. In some embodiments, IC chip package 100 can have a chip-on-wafer-on-substrate (CoWoS) structure. In some embodiments, IC chip package 100 can include (i) a package substrate 102, (ii) interconnect substrates 104A-104B, (iii) a chip layer 106, (iv) a redistribution layers (RDL) structure 110, (v) metal contact pads 112, (vi) conductive bonding structures 114A-114C, and (vii) encapsulating layers 116A-116C.

In some embodiments, package substrate 102 can be a laminate substrate (core-less) or can have cores (not shown). Package substrate 102 can include conductive lines 103A and conductive vias 103B that are electrically connected to conductive bonding structures 114A. Package substrate 102 can have a surface area greater than a surface area of each of interconnect substrates 104A-104B. In some embodiments, package substrate 102 can be disposed on and electrically connected to a circuit board (not shown) and can electrically connect IC chip package 100 to external devices through the circuit board.

In some embodiments, each of interconnect substrates 104A-104B can include an interposer structure having a semiconductor substrate 105A, conductive through-vias 105B, and an RDL structure 105C. In some embodiments, each of interconnect substrates 104A-104B can include conductive lines and conductive vias similar to those in package substrate 102, instead of conductive through-vias 105B and RDL structure 105C. In some embodiments, semiconductor substrate 105A can include a silicon substrate. In some embodiments, RDL structure 105C can include a dielectric layer 105D disposed on substrate 105A and RDLs 105E disposed in dielectric layer 105D. In some embodiments, conductive through-vias 105D and RDLs 105E can include a metal (such as copper and aluminum), a metal alloy (such as copper alloy and aluminum alloy), or a combination thereof. In some embodiments, dielectric layer 105D can include a stack of dielectric layers.

Each of interconnect substrates 104A-104B can be electrically connected to package substrate 102 through conductive bonding structures 114A and can be electrically connected to the components of chip layer 106 through conductive bonding structures 114B. In some embodiments, conductive bonding structures 114A-114B can include solder bumps. In some embodiments, conductive bonding structures 114A can include solder bumps or copper (Cu) bumps, and conductive bonding structures 114B can include copper pillars or micro bumps to form conductive bonding structures 114B with a smaller bonding pitch compared to the bonding pitch of conductive bonding structures 114A. The bond pitch is used herein to define a distance between adjacent conductive bonding structures.

In some embodiments, each of conductive bonding structures 114A can have a diameter of about 20 μm to about 50 μm, and each of conductive bonding structures 114B can have a diameter of about 2 μm to about 20 μm. In some embodiments, conductive bonding structures 114A can have a bonding pitch of about 30 μm to about 1000 μm, and conductive bonding structures 114B can have a bonding pitch of about 4 μm to about 40 μm. These dimensions of conductive bonding structures 114A-114B provide reliable electrical connections between chip layer 106 and interconnect substrates 104A-104B and between interconnect substrates 104A-104B and package substrate 102, without comprising the size of IC chip package 100. In some embodiments, encapsulating layer 116A can be disposed between package substrate 102 and interconnect substrates 104A-104B and can surround conductive bonding structures 114A. In some embodiments, encapsulating layer 116B can be disposed between interconnect substrates 104A-104B and chip layer 106 and can surround conductive bonding structures 114B. In some embodiments, encapsulating layers 116A-116B can include a molding compound, a molding underfill, an epoxy, or a resin.

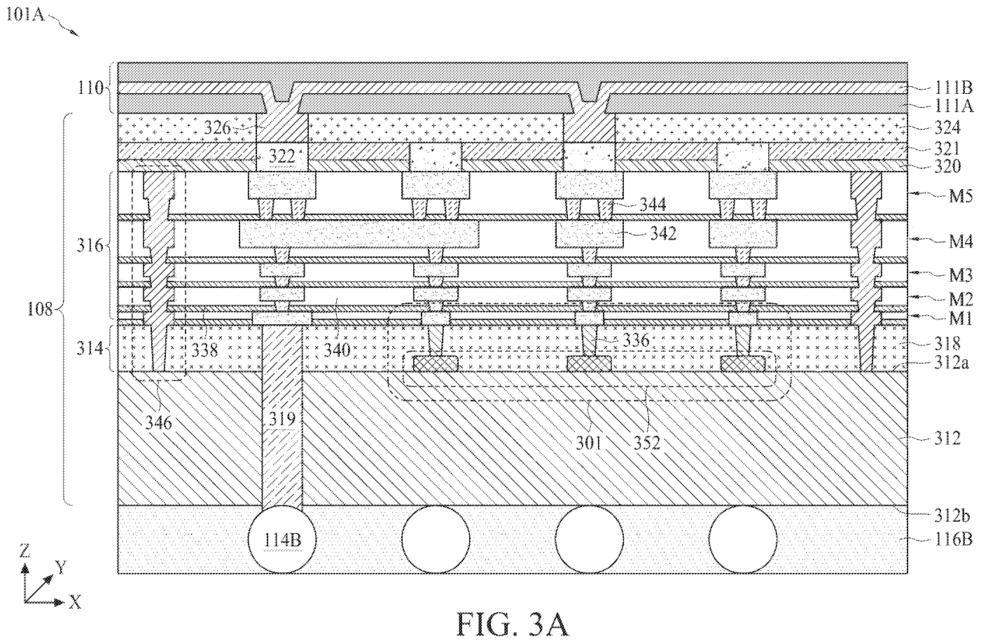

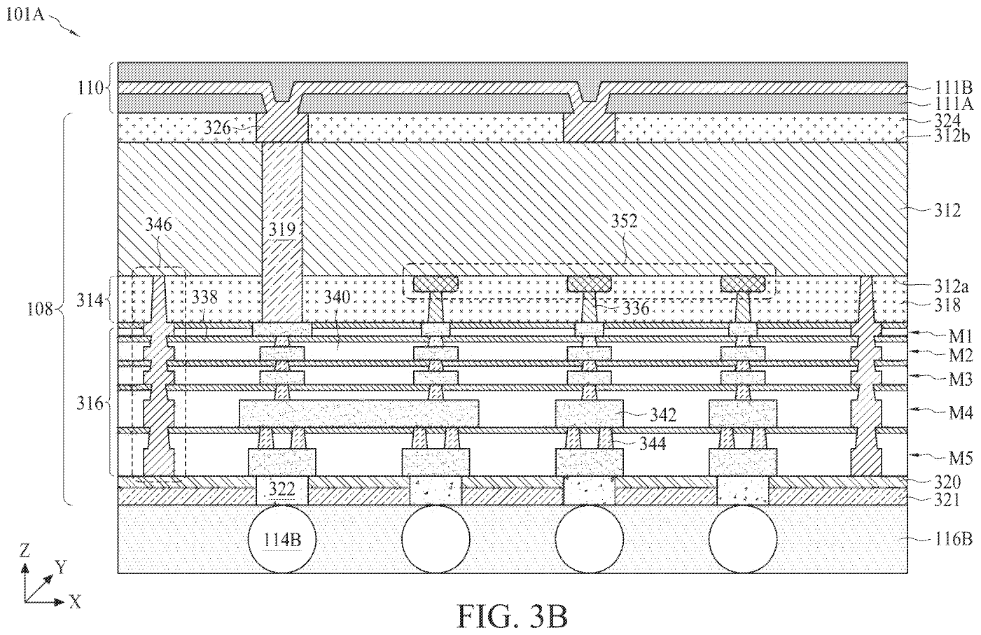

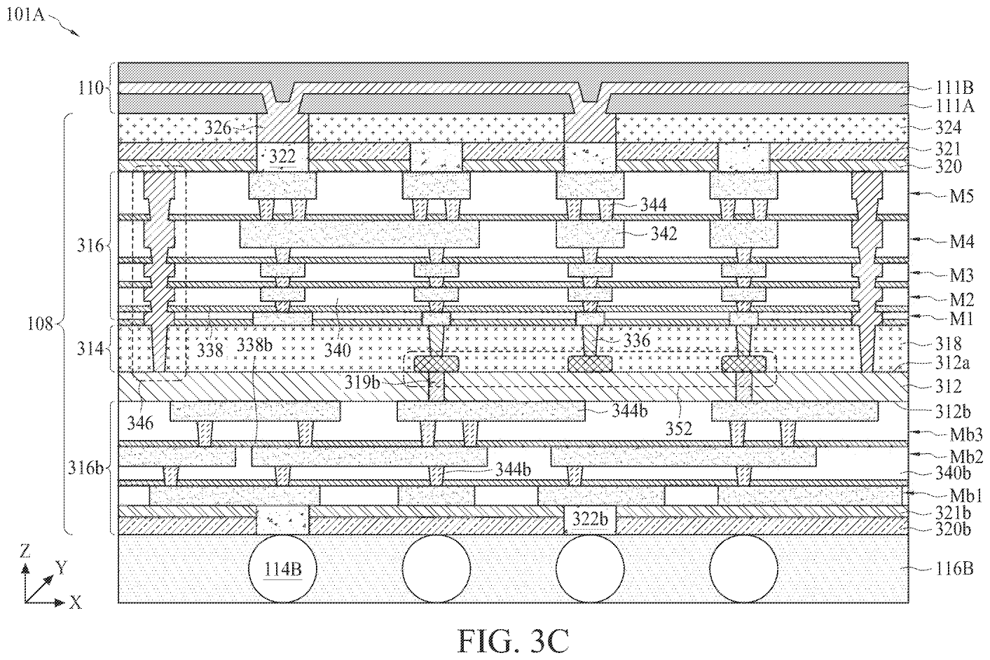

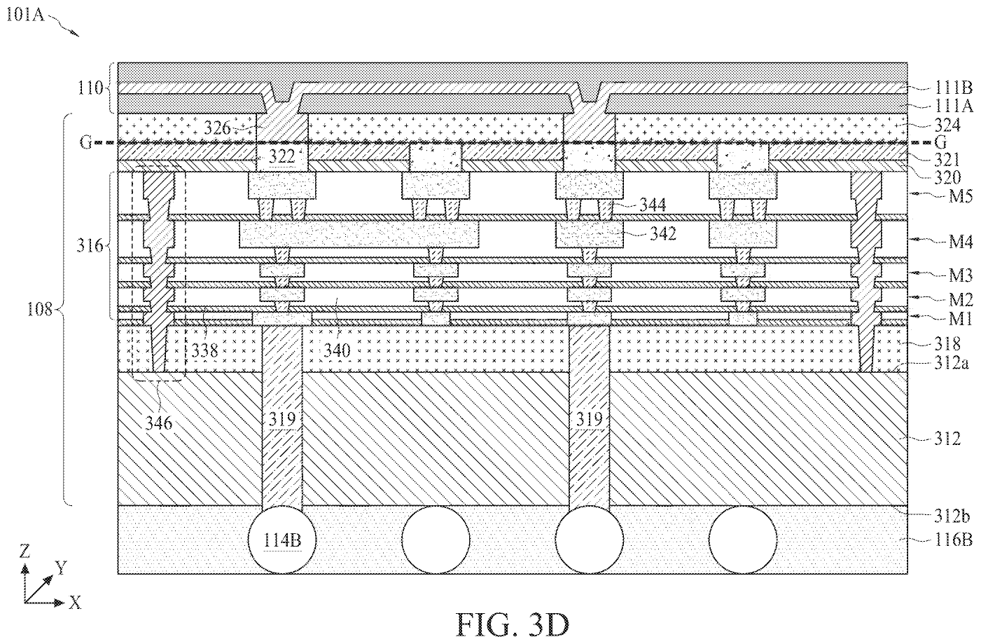

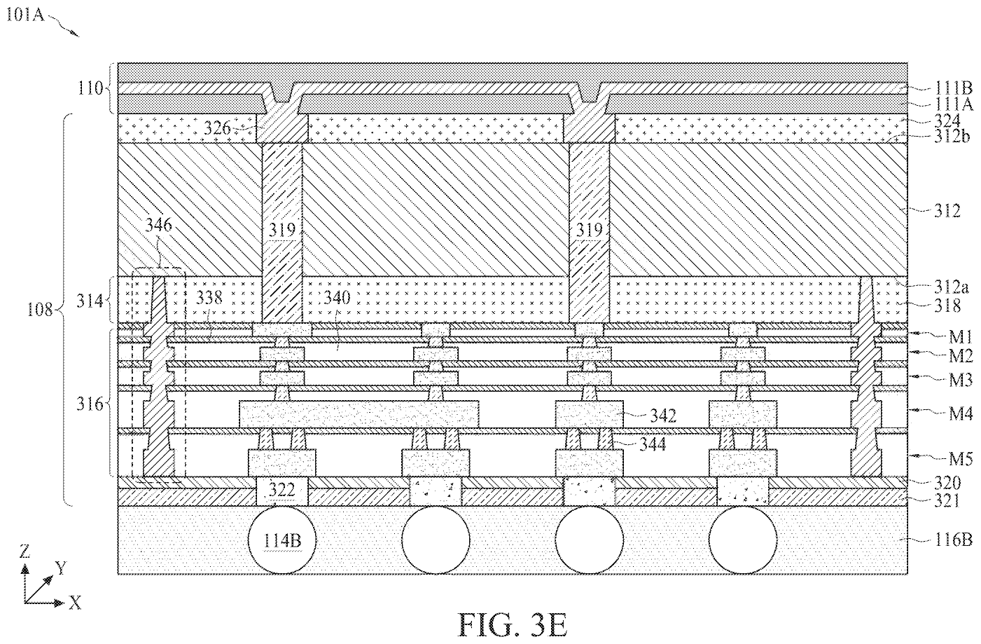

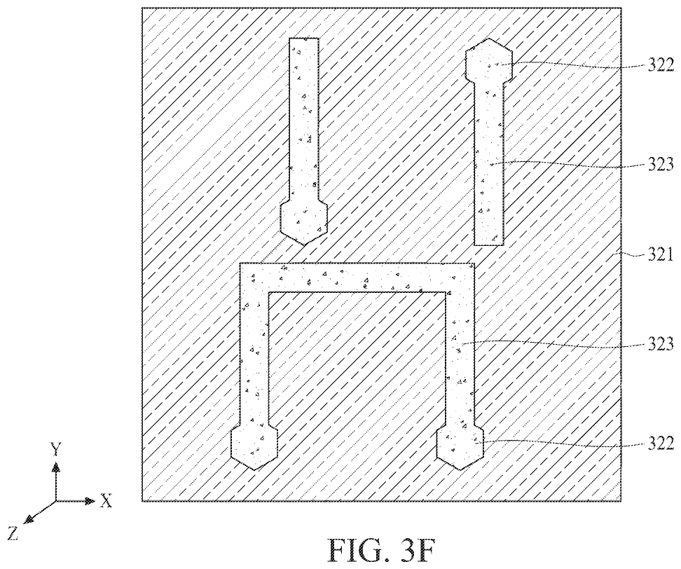

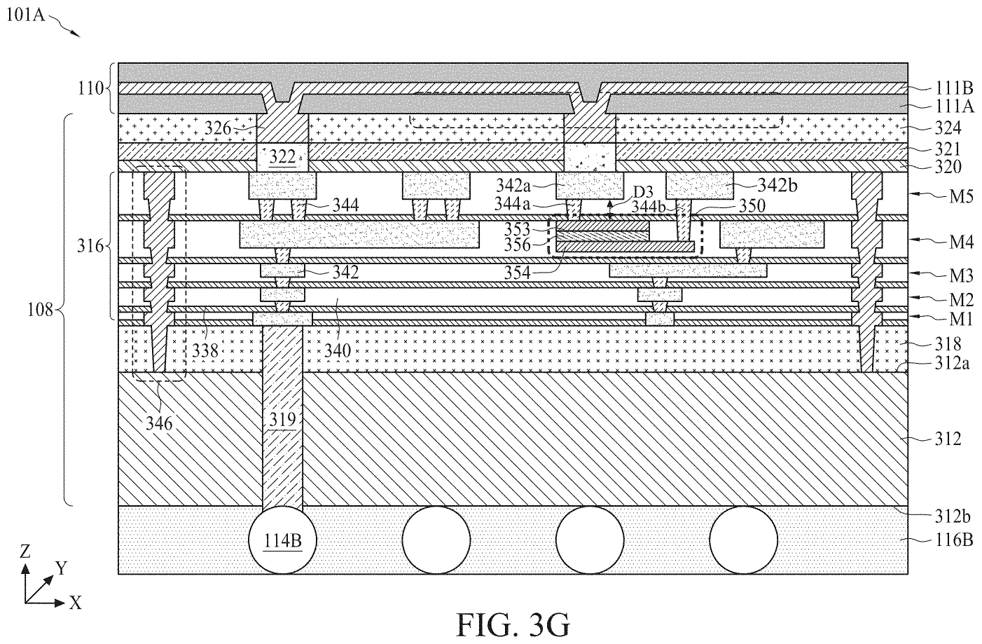

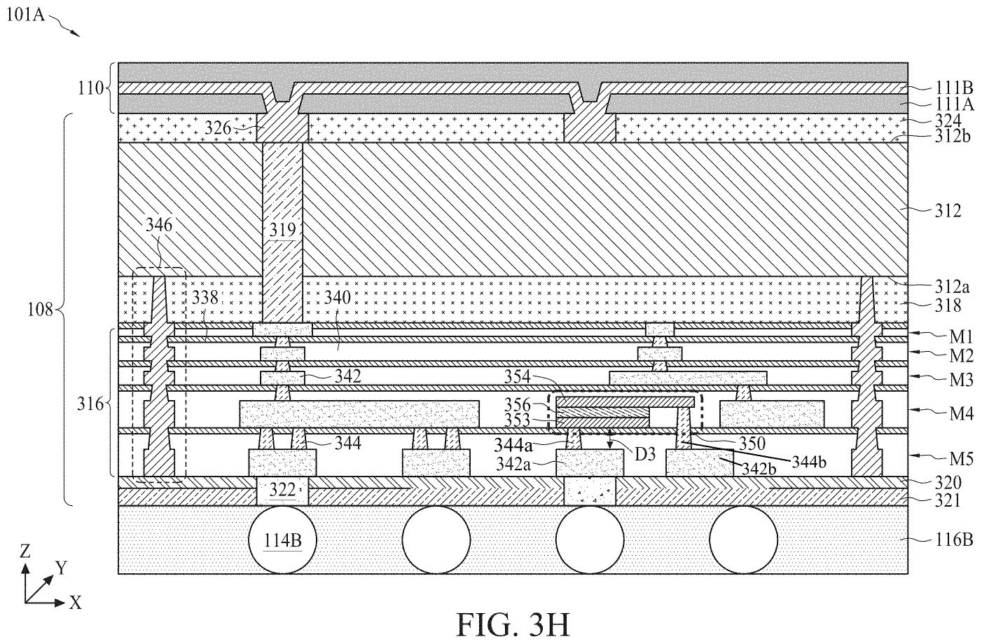

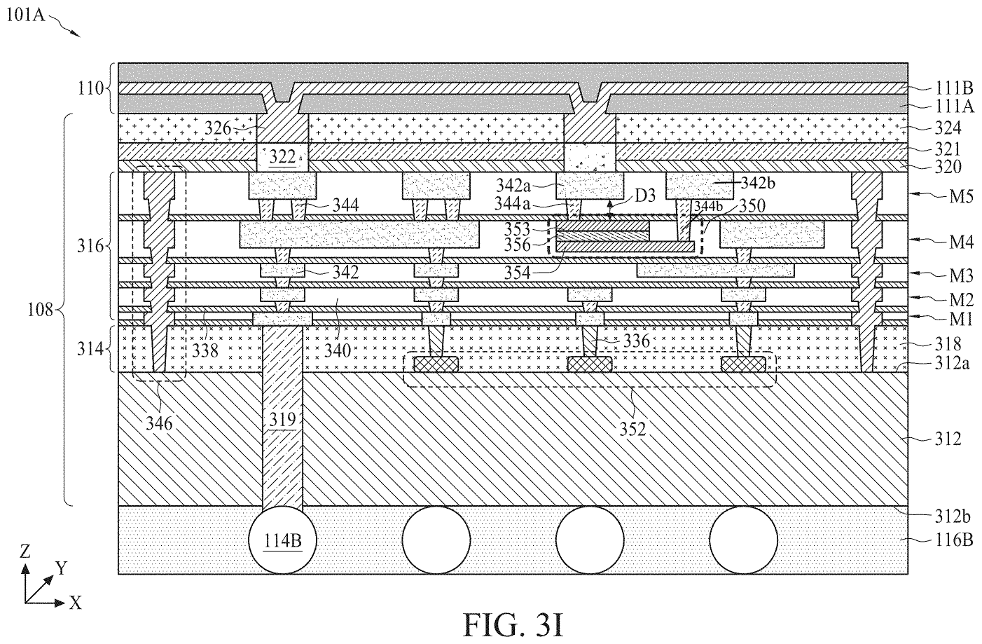

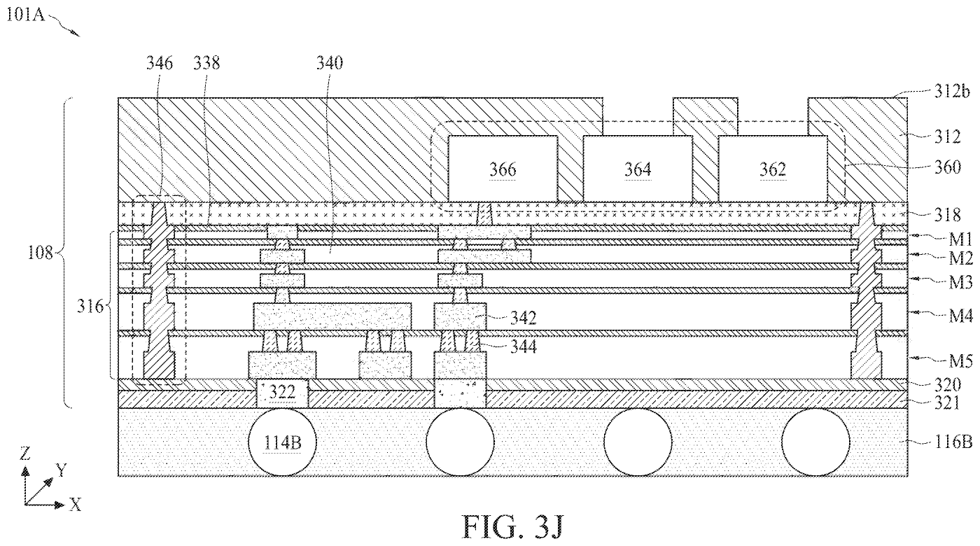

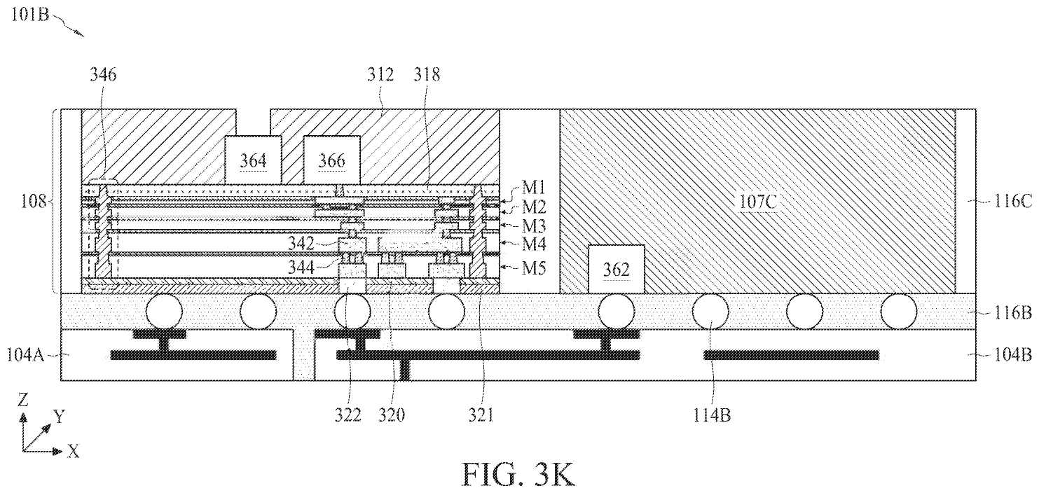

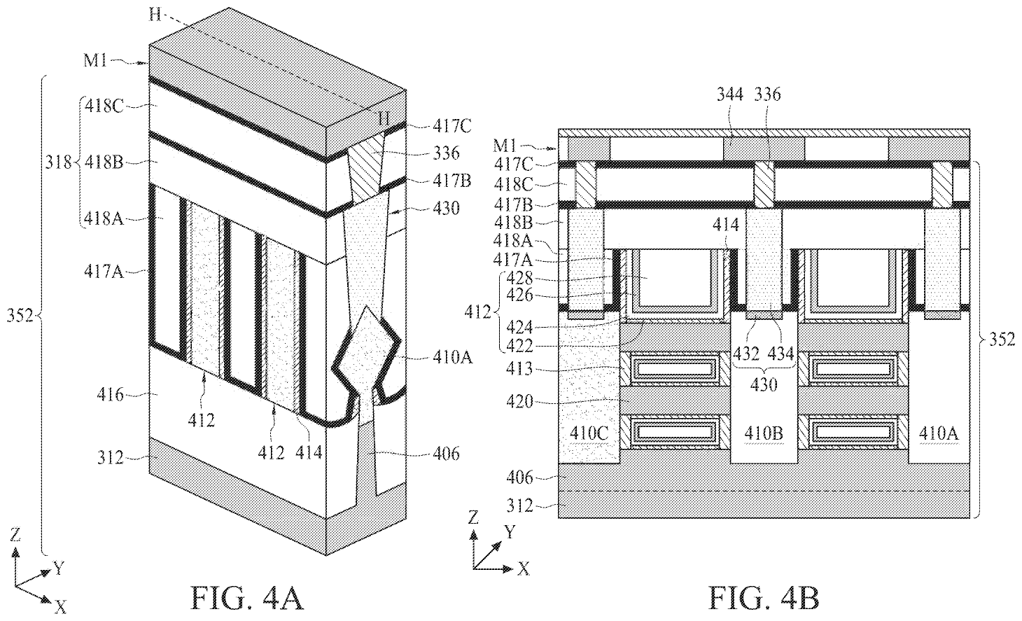

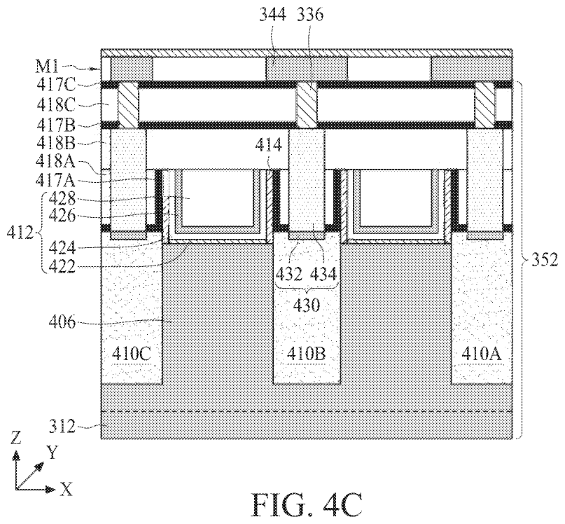

In some embodiments, chip layer 106 can include IC chips 107A-107D and an IC chip coupler 108. In some embodiments, IC chip coupler can be referred to as a “linkage IC chip,” an “IC chip connector,” or an “interconnecting IC chip. In some embodiments, IC chips 107A-107D and an IC chip coupler 108 can be separated from each other by encapsulating layer 116C. In some embodiments, encapsulating layer 116C can include a molding compound, a molding underfill, an epoxy, or a resin. In some embodiments, IC chip coupler 108 can include an IC chip and have a structure similar to or different from any one of IC chips 107A-107D, as described in detail below. In some embodiments, IC chip coupler 108 can include a signal routing chip without any active devices, as described in detail below. The term “signal” is used herein to refer to an electrical signal, unless mentioned otherwise. The structures of IC chips 107A-107D and IC chip coupler 108 are not illustrated in detail in FIG. 1A, but are described in detail below with reference to FIGS. 3A-3K and 4A-4C.

IC chips 107A-107B can be disposed on and electrically connected to interconnect substrate 104A through conductive bonding structures 114A. IC chips 107C-107D can be disposed on and electrically connected to interconnect substrate 104B through conductive bonding structures 114A. In some embodiments, IC chip coupler 108 can be disposed on and electrically connected to interconnect substrates 104A-104B through conductive bonding structures 114A-114B. As a result, IC chip coupler 108 can electrically connect one or more IC chips (e.g., IC chips 107A and/or 107B) on interconnect substrate 104A to one or more IC chips (e.g., IC chips 107C and/or 107D) on interconnect substrate 104B and can function as a signal transmission bridge between the one or more IC chips on interconnect substrates 104A and 104B. In some embodiments, IC chip coupler 108 can also function as a terminal for voltage input and supply power from IC chip coupler 108 to package substrate 102.

With the use of IC chip coupler 108 in IC chip package 100, signals can be transmitted between IC chips (e.g., IC chips 107A-107B and IC chips 107C-107D) on the same surface level, but on different interconnect substrates by propagating through a single level of substrates, such as interconnect substrates 104A and 104B. For example, with the use of IC chip coupler 108, signals can be transmitted from IC chip 107B to IC chip 107C by propagating along signal transmission paths 109A and 109B through interconnect substrates 104A and 104A. On the other hand, in the absence of IC chip coupler 108, the signals can be transmitted from IC chip 107B to IC chip 107C by propagating along a signal transmission path 109C, which extends through multiple level of substrates, such as interconnect substrates 104A-104B and package substrate 102. As a result, the path length of signal transmission path 109C is greater than the total path length of signal transmission paths 109A-109B.

Thus, with the use of IC chip coupler 108, signal transmission path lengths between IC chips on the same surface level, but on different interconnect substrates can be reduced, which reduces signal transmission path resistance and increases signal transmission speed and bandwidth of the IC chips in IC chip package 100. In some embodiments, the signal transmission path resistance in IC chip package 100 can reduced by about 30% to about 50% compared to IC chip packages without IC chip coupler 108. In addition, with the use of IC chip coupler 108, the total number of electrical connections per unit area of interconnect substrates 104A-104B can be increased without increasing the size of IC chip package 100.

In some embodiments, a height H1 of IC chip coupler 108 can be substantially equal to heights H2-H5 of IC chips 107A-107D and heights H2-H5 can be substantially equal to each other. In some embodiments, a height difference between height H1 and any of heights H2-H5 can be less than about 1000 μm. In some embodiments, a height difference between height H1 and any of heights H2-H5 can range from about 0 μm to about 10 μm. In some embodiments, top surfaces of IC chips 107A-107D and IC chip coupler 108 can be substantially coplanar and bottom surfaces of IC chips 107A-107D and IC chip coupler 108 can be substantially coplanar. In some embodiments, minimizing the height difference between IC chip coupler 108 and IC chips 107A-107D and the non-coplanarity between IC chip coupler 108 and IC chips 107A-107D, increases the bonding reliability and bonding stability of conductive bonding structures 114AB between IC chip coupler 108 and interconnect substrates 104A-104B.

In some embodiments, interconnect substrates 104A-104B are separated from each other by a distance D1 of about 10 μm to about 200 μm. This dimension range of distance Dl minimizes the probability of collision between interconnect substrates 104A-104B during the fabrication of IC chip package 100 and maximizes the bonding surface area between IC chip coupler 108 and interconnect substrates 104A-104B without comprising the size of IC chip package 100. In some embodiments, IC chip coupler 108 and IC chips 107A-107D can be separated from each other by a distance D2 of about 5 μm to about 80 μm. This dimension range of distance D2 minimizes the probability of collision between IC chip coupler 108 and IC chips 107A-107D during the fabrication of IC chip package 100 and minimizes the coupling effects between IC chip coupler 108 and IC chips 107A-107D without comprising the size of IC chip package 100.

In some embodiments, RDL structure 110 can be disposed on and electrically connected to IC chip coupler 108 and IC chips 107A-107D. RDL structure 110 can include a dielectric layer 111A and RDLs 111B disposed in dielectric layer 111A. RDLs 111B can be configured to fan out IC chip coupler 108 and IC chips 107A-107D such that electrical connections on each of IC chip coupler 108 and IC chips 107A-107D can be redistributed to a greater area than the individual IC chips, and consequently increase the number of electrical connections. In some embodiments, RDLs 111B can be electrically connected to conductive bonding structures 114C through metal contact pads 112. In some embodiments, metal contact pads 112 and RDLs 111B can include a material similar to or different from each other. In some embodiments, metal contact pads 112 and RDLs 111B can include a metal (such as copper and aluminum), a metal alloy (such as copper alloy and aluminum alloy), or a combination thereof. In some embodiments, dielectric layer 111A can include a stack of dielectric layers.

FIGS. 1B-1F illustrate different top-down views of IC chip package 100 along line A-A of FIG. 1A and along an XY-plane, according to some embodiments. The cross-sectional view of FIG. 1A can be along line B-B of FIG. 1B, along line C-C of FIG. 1C, along line D-D of FIG. 1D, along line E-E of FIG. 1E, or along line F-F of FIG. 1F, according to some embodiments. In FIGS. 1B-1F, IC chip coupler 108 and interconnect substrates 104A-1041 of IC chip package 100 are shown, and the other elements of IC chip package 100 visible in top-down views along line A-A are not shown for simplicity. The discussion of elements in FIGS. 1A-1F with the same annotations applies to each other, unless mentioned otherwise.

In some embodiments, IC chip coupler 108 can be electrically connected to two interconnect substrates 104A-104B (shown in FIG. 1B), three interconnect substrates 104A-104C (shown in FIG. 1C), four interconnect substrates 104A-104B and 104D-104E (shown in FIG. 1D), six interconnect substrates 104A-104B and 104F-1041 (shown in FIG. 1E), or any number of interconnect substrates of IC chip package 100 with conductive bonding structures 114B (not shown in FIGS. 1B-1F). IC chip coupler 108 can serve as the signal transmission bridge between IC chips (not shown in FIGS. 1B-1F) electrically connected to interconnect substrates 104A-1041. In some embodiments, two IC chip couplers 108 (shown in FIG. 1F), or any number of IC chip couplers 108 can be electrically connected to interconnect substrates. In some embodiments, the two or more IC chip couplers 108 can have surface areas substantially equal to each other (shown in FIG. 1F) or different from each other (not shown). In some embodiments, each of the two or more IC chip couplers 108 can be electrically connected to the same number of interconnect substrates (shown in FIG. 1F), or different number of interconnect substrates (not shown).

Referring to FIG. 1B, in some embodiments, IC chip coupler 108 can include (i) overlapping regions 118A that overlap with interconnect substrates 104A-104B, and (ii) I-shaped non-overlapping region 118B that does not overlap with interconnect substrates 104A-104B. Referring to FIG. 1C, in some embodiments, IC chip coupler 108 can include (i) overlapping regions 118A that overlap with interconnect substrates 104A-104C, and (ii) T-shaped non-overlapping region 118B that does not overlap with interconnect substrates 104A-104C. Referring to FIG. 1D, in some embodiments, IC chip coupler 108 can include (i) overlapping regions 118A that overlap with interconnect substrates 104A-104B and 104D-104E, and (ii) plus-shaped non-overlapping region 118B that does not overlap with interconnect substrates 104A-104B and 104D-104E.

Referring to FIG. 1E, in some embodiments, IC chip coupler 108 can include (i) overlapping regions 118A that overlap with interconnect substrates 104A-104B and 104F-1041, and (ii) H-shaped non-overlapping region 118B that does not overlap with interconnect substrates 104A-104B and 104F-1041. Referring to FIG. 1F, in some embodiments, IC chip couplers 108 can each include overlapping regions 118A and non-overlapping region 118B similar to that shown in FIG. 1D. Referring to FIGS. 1B-1F, overlapping regions 118A are electrically connected to the interconnect substrates with conductive bonding structures 114B (not shown in FIGS. 1B-1F). Non-overlapping regions 118B are in physical contact with encapsulating layer 116B (not shown in FIGS. 1B-1F). In some embodiments, for each IC chip coupler 108 shown in FIGS. 1B-1F, surface areas of overlapping regions 118A can be equal to or different from each other.

In some embodiments, the surface area of IC chip coupler 108, the relative position of IC chip coupler 108 to the underlying interconnect substrates (e.g., interconnect substrates 104A-1041), and/or distances D1 between the underlying interconnect substrates (shown in FIGS. 1A-1F) can be based on one or more criteria. These one or more criteria can be set to achieve adequate bonding reliability and bonding stability between IC chip coupler 108 and interconnect substrates 104A-1041 with conductive bonding structures 114B.

In some embodiments, for each IC chip coupler 108 shown in FIGS. 1B-1F, these criteria can include (i) the smallest dimension of each overlapping region 118A along an X-axis or a Y-axis is greater than about 10 μm and ranges from about 11 μm to about 200 μm, (ii) the total surface area of overlapping regions 118A is equal to or greater than about 50% of the total surface area of non-overlapping region 118B, (iii) the total surface area of overlapping regions 118A is equal to or greater than about 20% of the total surface area of IC chip coupler 108, (iv) the surface area of each overlapping region 118A is greater than about 5% of the total surface area of overlapping regions 118A, (v) if the surface areas of overlapping regions 118A are unequal to each other, the surface area of overlapping region 118A with the smallest surface area is equal to or greater than about 10% of the surface area of overlapping region 118A with the largest surface area, and/or (vi) if the surface areas of overlapping regions 118A are unequal to each other, a difference between the surface areas of any two overlapping regions 118A is equal to or less than about 80% of the total surface area of overlapping regions 118A.

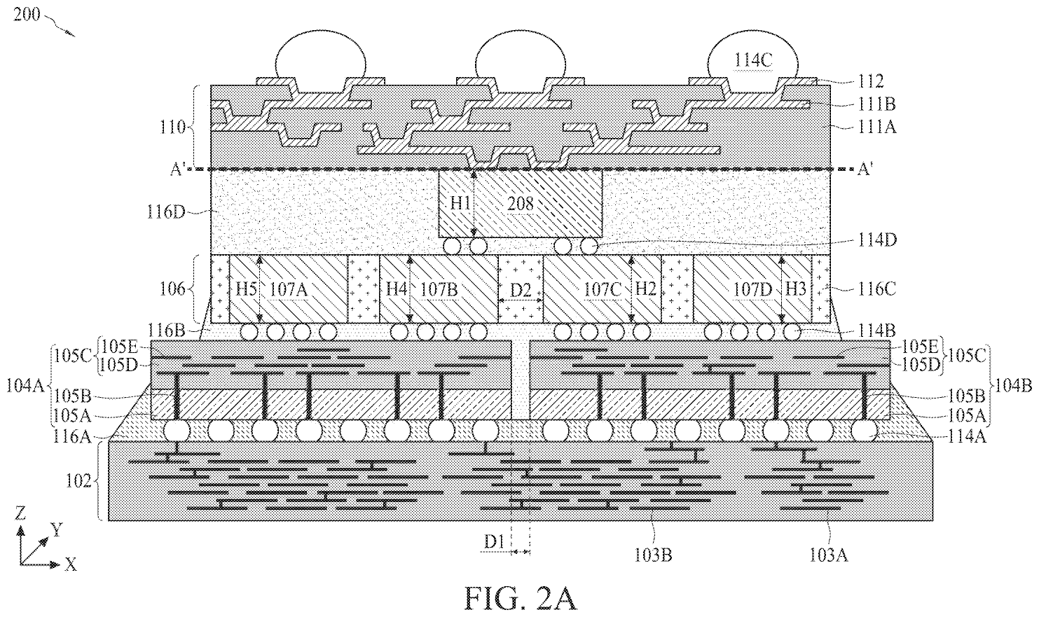

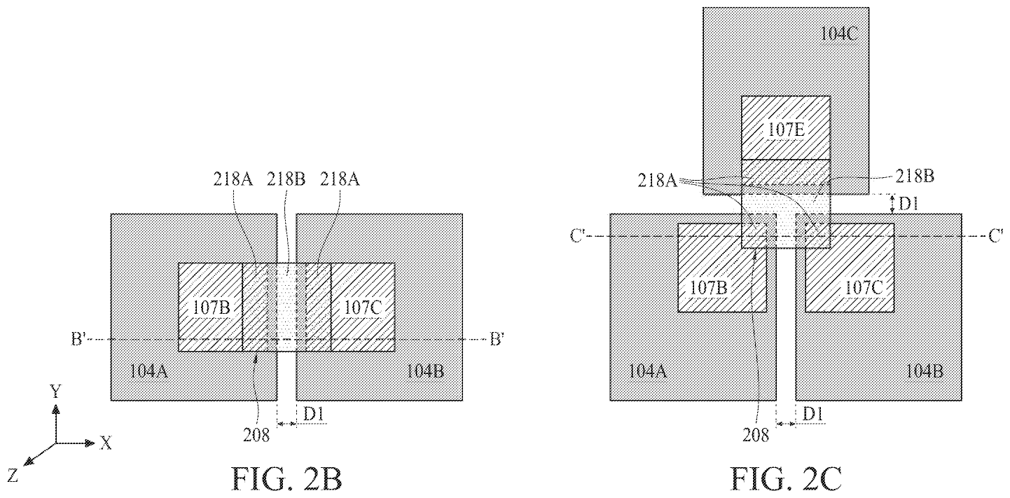

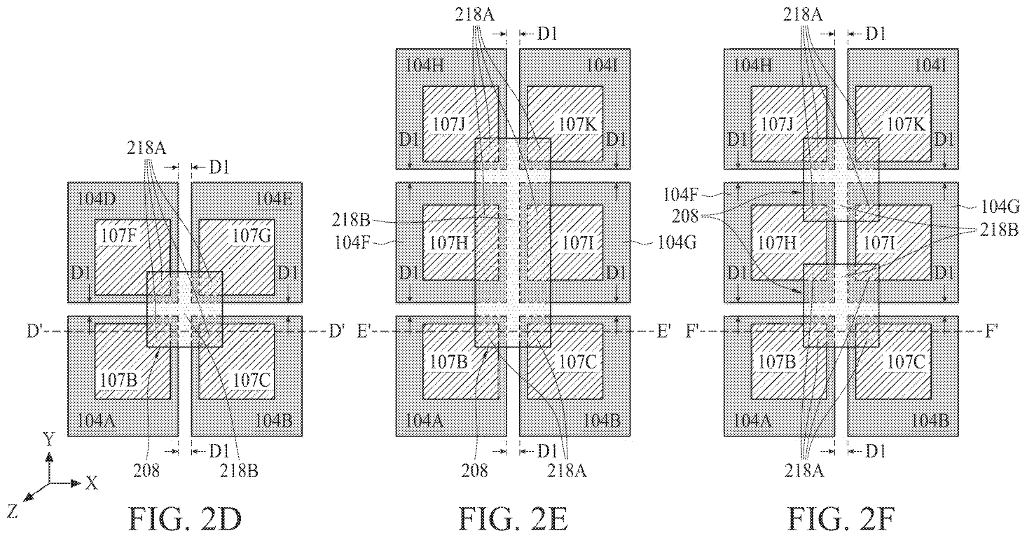

FIG. 2A illustrates a cross-sectional view of an IC chip package 200, according to some embodiments. The discussion of IC chip package 100 can applies to IC chip package 200, unless mentioned otherwise. The discussion of elements in FIGS. 1A-1F and 2A with the same annotations applies to each other, unless mentioned otherwise.

In some embodiments, IC chip package 200 can include an IC chip coupler 208 disposed in encapsulating layer 116D, which can be similar to encapsulating layer 116C, and RDL structure 110 can be disposed on IC chip coupler 208 and encapsulating layer 116D. In some embodiments, IC chip coupler 208 can be disposed on and electrically connected to IC chips (e.g., IC chips 107B-107C) on the same surface level, but on different interconnect substrates (e.g., interconnect substrates 104A-104B) with conductive bonding structures 114D, which can be similar to conducive bonding structures 114B. In some embodiments, unlike IC chip package 100, chip layer 106 of IC chip package 200 does not include an IC chip coupler on the same surface level as IC chips 107A-107D.

Similar to IC chip coupler 108, IC chip coupler 208 can function as a signal transmission bridge between IC chips 107B-107C and enable signals to be transmitted between IC chips 107B-107C through IC chip coupler 208 without propagating through signal transmission path 109C, as described above with reference to FIG. 1A. The path length of signal transmission path 109C is greater than the total path length of signal transmission between IC chips 107B-107C through IC chip coupler 208. Thus, with the use of IC chip coupler 208, signal transmission path lengths between IC chips on the same surface level, but on different interconnect substrates can be reduced, which reduces signal transmission path resistance and increases signal transmission speed and bandwidth of the IC chips in IC chip package 100.

FIGS. 2B-2F illustrate different top-down views of IC chip package 200 along line A′-A′ of FIG. 2A and along an XY-plane, according to some embodiments. The cross-sectional view of FIG. 2A can be along line B′-B′ of FIG. 2B, along line C′-C′ of FIG. 2C, along line D′-D′ of FIG. 2D, along line E′-E′ of FIG. 2E, or along line F′-F′ of FIG. 2F, according to some embodiments. In FIGS. 2B-2F, IC chip coupler 208, IC chips 107B-107C and 107E-107K, and interconnect substrates 104A-1041 of IC chip package 200 are shown, and the other elements of IC chip package 200 visible in top-down views along line A′-A′ are not shown for simplicity. The discussion of elements in FIGS. 1A-1F and 2A-2F with the same annotations applies to each other, unless mentioned otherwise.

In some embodiments, IC chip coupler 208 can be electrically connected to (i) two IC chips 107B-107C on two different interconnect substrates 104A-104B (shown in FIG. 2B), (ii) three IC chips 107B-107C and 107E on three different interconnect substrates 104A-104C (shown in FIG. 2C), (iii) four IC chips 107B-107C and 107F-107G on four different interconnect substrates 104A-104B and 104D-104E (shown in FIG. 2D), (v) six IC chips 107B-107C and 107H-107K on six different interconnect substrates 104A-104B and 104F-104I (shown in FIG. 2E), or (vi) any number of interconnect substrates of IC chip package 200 with conductive bonding structures 114D (not shown in FIGS. 2B-2F). In some embodiments, IC chips 107B-107C and 107E-107K can be electrically connected to interconnect substrates 104A-104I with conductive bonding structures 114B (not shown in FIGS. 2B-2F).

In some embodiments, two IC chip couplers 208 (shown in FIG. 2F), or any number of IC chip couplers 208 can be electrically connected to IC chips. In some embodiments, the two or more IC chip couplers 208 can have surface areas substantially equal to each other (shown in FIG. 1F) or different from each other (not shown). In some embodiments, each of the two or more IC chip couplers 208 can be electrically connected to the same number of IC chips (shown in FIG. 2F) or different number of IC chips (not shown). In some embodiments, the surface area of IC chip coupler 208 can be substantially equal to or different from IC chips 107B-107C and 107H-107K.

Referring to FIG. 2B, in some embodiments, IC chip coupler 208 can include (i) overlapping regions 218A that overlap with IC chips 107B-107C, and (ii) I-shaped non-overlapping region 218B that does not overlap with IC chips 107B-107C. Referring to FIG. 2C, in some embodiments, IC chip coupler 208 can include (i) overlapping regions 218A that overlap with IC chips 107B-107C and 107E, and (ii) T-shaped non-overlapping region 218B that does not overlap with IC chips 107B-107C and 107E. Referring to FIG. 2D, in some embodiments, IC chip coupler 208 can include (i) overlapping regions 218A that overlap with IC chips 107B-107C and 107F-107G, and (ii) plus-shaped non-overlapping region 218B that does not overlap with IC chips 107B-107C and 107F-107G.

Referring to FIG. 2E, in some embodiments, IC chip coupler 208 can include (i) overlapping regions 218A that overlap with IC chips 107B-107C and 107H-107K, and (ii) H-shaped non-overlapping region 218B that does not overlap with IC chips 107B-107C and 107H-107K. Referring to FIG. 2F, in some embodiments, IC chip couplers 208 can each include overlapping regions 218A and non-overlapping region 218B similar to that shown in FIG. 2D. Referring to FIGS. 2B-2F, overlapping regions 218A are electrically connected to the IC chips with conductive bonding structures 114D (not shown in FIGS. 2B-2F). Non-overlapping regions 218B are in physical contact with encapsulating layer 116D (not shown in FIGS. 2B-2F). In some embodiments, for each IC chip coupler 208 shown in FIGS. 2B-2F, surface areas of overlapping regions 218A can be equal to or different from each other.

In some embodiments, the surface area of IC chip coupler 208, the relative position of IC chip coupler 208 to the underlying IC chips (e.g., IC chips 107B-107C and 107E-107K), and/or distances D2 between the underlying IC chips can be based on one or more criteria. These one or more criteria can be set to achieve adequate bonding reliability and bonding stability between IC chip coupler 208 and IC chips 107B-107C and 107E-107K with conductive bonding structures 114D.

In some embodiments, for each IC chip coupler 208 shown in FIGS. 2B-2F, these criteria can include (i) the smallest dimension of each overlapping region 218A along an X-axis or a Y-axis is greater than about 10 μm and ranges from about 11 μm to about 200 μm, (ii) the total surface area of overlapping regions 218A is equal to or greater than about 50% of the total surface area of non-overlapping region 218B, (iii) the total surface area of overlapping regions 218A is equal to or greater than about 20% of the total surface area of IC chip coupler 208, (iv) the surface area of each overlapping region 218A is greater than about 5% of the total surface area of overlapping regions 218A, (v) if the surface areas of overlapping regions 218A are unequal to each other, the surface area of overlapping region 218A with the smallest surface area is equal to or greater than about 10% of the surface area of overlapping region 218A with the largest surface area, and/or (vi) if the surface areas of overlapping regions 218A are unequal to each other, a difference between the surface areas of any two overlapping regions 218A is equal to or less than about 80% of the total surface area of overlapping regions 218A.

The number of interconnect substrates, IC chips, and IC chip couplers illustrated in FIGS. 1A-1F and 2A-2G are exemplary. IC chip packages 100 and/or 200 can include any number of interconnect substrates, IC chips, and IC chip couplers.

FIGS. 3A-3E and 3G-3J are enlarged views of region 101A of FIG. 1A, and FIG. 3K is an enlarged view of region 101B of FIG. 1A, according to some embodiments. FIGS. 3A-3E and 3G-3K illustrate different cross-sectional views of IC chip coupler 108 and different electrical connection configurations of IC chip coupler 108 with conductive bonding structures 114B and RDLs 111B, according to some embodiments. FIG. 3F illustrates a top-down view of IC chip coupler 108 along line G-G of FIG. 3D, according to some embodiments. The discussion of elements in FIGS. 1A-1F, 2A-2F, and 3A-3K with the same annotations applies to each other, unless mentioned otherwise.

Referring to FIGS. 3A-3C, in some embodiments, IC chip coupler 108 can be a functional IC chip and can include one or more circuits with active devices (e.g., FET 352), and routing structures, such as interconnect structures 316 and/or conductive through-vias 319.

Referring to FIG. 3A, in some embodiments, IC chip coupler 108 can include (i) a substrate 312 with a front-side surface 312a and a back-side surface 312b, (ii) a device layer 314 disposed on front-side surface 312a of substrate 312, (iii) a front-side interconnect structure 316 disposed on device layer 314, (iv) a conductive through-via 319 disposed in substrate 312 and device layer 314, (v) passivation layers 320-321 disposed on front-side interconnect structure 316, (vi) conductive pads 122 disposed within passivation layers 320-321 and on front-side interconnect structure 316, (vii) a stress buffer layer 324 disposed on passivation layer 321 and conductive pads 322, (vii) conductive vias 326 disposed within stress buffer layer 324 and on conductive pads 322, (viii) barrier structures 346 disposed in device layer 314 and front-side interconnect structure 316.

In some embodiments, substrate 312 can be a semiconductor material, such as silicon, germanium (Ge), silicon germanium (SiGe), a silicon-on-insulator (SOI) structure, other suitable semiconductor materials, and a combination thereof. Further, substrate 312 can be doped with p-type dopants (e.g., boron, indium, aluminum, or gallium) or n-type dopants (e.g., phosphorus or arsenic).

In some embodiments, device layer 314 can include semiconductor devices, such as GAA FETs (e.g., GAA FET 352 shown in FIG. 4B), finFETs (e.g., finFET 352 shown in FIG. 4C), and MOSFETs, conductive vias 336, and interlayer dielectric (ILD) layer 318. The semiconductor devices can be electrically connected to front-side interconnect structure 316 through conductive vias 336 and can be electrically connected to RDL structure 110 through front-side interconnect structure 316, conductive pads 322, and conductive vias 326.

In some embodiments, front-side interconnect structure 316 can include interconnect layers M1-M5. Though five interconnect layers M1-M5 are discussed with reference to FIGS. 3A-3E and 3G-3K, front-side interconnect structure 316 can have any number of interconnect layers. Each of interconnect layers M1-M5 can include an etch stop layer (ESL) 338 and an ILD layer 340. ESLs 338 can include a dielectric material, such as aluminum oxide (AlₓO_{y}), nitrogen doped silicon carbide (SiCN), and oxygen doped silicon carbide (SiCO) with a dielectric constant ranging from about 4 to about 10.

In some embodiments, ILD layers 340 can include a low-k (LK) or extra low-k (ELK) dielectric material with a dielectric constant lower than that of silicon oxide (e.g., dielectric constant between about 2 and about 3.7). In some embodiments, the LK or ELK dielectric material can include silicon oxycarbide (SiOC), nitrogen doped silicon carbide (SiCN), silicon oxycarbon nitride (SiCON), or oxygen doped silicon carbide. In some embodiments, ILD layers 340 can include one or more layers of insulating carbon material with a low dielectric constant of less than about 2 (e.g., ranging from about 1 to about 1.9). In some embodiments, the one or more layers of insulating carbon material can include one or more fluorinated graphene layers with a dielectric constant ranging from about 1 to about 1.5 or can include one or more graphene oxide layers.

In some embodiments, each of interconnect layers M1-M5 can further include one or more metal lines 342 and one or more conductive vias 344. The layout and number of metal lines 342 and conductive vias 344 are exemplary and not limiting and other layout variations of metal lines 342 and conductive vias 344 are within the scope of this disclosure. There may be metal routings between FET 352 and interconnect layers M1-M5 and between conductive through-via 319 and interconnect layers M1-M5 that are not visible in the cross-sectional view of FIG. 3A.

Each of metal lines 342 can be disposed in ILD layer 340 and each of conductive vias 344 can be disposed in ILD layer 340 and ESL 338. Conductive vias 344 provide electrical connections between metal lines 342 of adjacent interconnect layers. In some embodiments, conductive vias 344 can include an electrically conductive material, such as Cu, Ru, Co, Mo, a Cu alloy (e.g., Cu—Ru, Cu—Al, or copper-manganese (CuMn)), carbon nanotubes, graphene layers, and any other suitable conductive material. In some embodiments, metal lines 342 can include electrically conductive material, such as Cu, Ru, Co, Mo, carbon nanotubes, graphene layers, and any other suitable conductive material.

In some embodiments, barrier structures 346 can be configured to protect elements in device layer 314 and front-side interconnect structure 316 from processing chemicals (e.g., etchants) and/or moisture during the fabrication and/or the packaging of IC chip coupler 108. Barrier structures 346 can include conductive material similar to the material of metal lines 342.

In some embodiments, passivation layer 320 can include an oxide layer. The oxide layer can include silicon oxide (SiO₂) or another suitable oxide-based dielectric material. In some embodiments, passivation layer 321 can include a nitride layer. The nitride layer can include silicon nitride (SiN) or another suitable nitride-based dielectric material that can provide moisture control to front-side interconnect structure 316 and device layer 314 during the formation of structures overlying passivation layer 321 and/or during the packaging of IC chip coupler 108. In some embodiments, conductive pads 322 can include aluminum.

In some embodiments, stress buffer layer 324 disposed on passivation layer 321 can mitigate the mechanical and/or thermal stress induced during packaging of IC chip coupler 108, such as during the formation of RDL structure 110 and/or during the formation of conductive bonding structures 114C (shown in FIG. 1A). In some embodiments, stress buffer layer 324 can include a dielectric material, such a low-k dielectric material with a dielectric constant (k) less than about 3.5, an undoped silicate glass (USG), and a fluorinated silica glass (FSG). In some embodiments, stress buffer layer 324 can include a polymeric material, such as polyimide, polybenzoxazole (PBO), an epoxy-based polymer, a phenol-based polymer, and benzocyclobutene (BCB).

In some embodiments, conductive vias 326 disposed within stress buffer layer 324 can electrically connect front-side interconnect structure 316 to RDLs 111B. In some embodiments, conductive vias 326 can include (i) a conductive material, such as copper (Cu), aluminum (Al), tungsten (W), titanium (Ti), tantalum (Ta), titanium nitride (TiN), tantalum nitride (TaN), titanium aluminum (TiAl), titanium aluminum nitride (TiAlN), and tungsten nitride (WN); (ii) a metal alloy, such as copper alloys and aluminum alloys; and (iii) a combination thereof. In some embodiments, conductive vias 126 can include a titanium (Ti) liner and a copper (Cu) fill. The titanium liner can be disposed on bottom surfaces and sidewalls of conductive vias 326.

In some embodiments, conductive through-via 319 can include a metal (such as copper and aluminum), a metal alloy (such as copper alloy and aluminum alloy), or a combination thereof. In some embodiments, conductive through-via 319 can include a titanium liner and a copper fill. The titanium liner can be disposed on bottom surfaces and sidewalls of conductive through-via 319.

In some embodiments, IC chip coupler 108 can be positioned with the back-side of IC chip coupler 108 (also referred to as “substrate-side of IC chip coupler 108”) facing conductive bonding structures 114B. In this position, IC chip coupler 108 can be electrically connected to conductive bonding structures 114B with one or more conductive through-vias 319, and can be electrically connected to RDL structure 110 with one or more conductive pads 322 and vias 326. There may be one or more conductive through-vias 319 that electrically connect front-side interconnect structure 316 to conductive bonding structures 114B that are not visible in the cross-sectional view of FIG. 3A.

The discussion of the structure of FIG. 3A applies to the structure of FIG. 3B, unless mentioned otherwise. Referring to FIG. 3B, in some embodiments, IC chip coupler 108 can be positioned with the front-side of IC chip coupler 108 (also referred to as “interconnect-side of IC chip coupler 108”) facing conductive bonding structures 114B. In this position, IC chip coupler 108 can be electrically connected to conductive bonding structures 114B with one or more conductive pads 322 and can be electrically connected to RDL structure 110 with one or more conductive through-vias 319 and conductive vias 326. The one or more conductive pads 322 can electrically connect front-side interconnect structure 316 to conductive bonding structures 114B. In some embodiments, stress buffer layer 324 and conductive vias 326 can be disposed on back-side surface 312b of substrate 312, instead of on passivation layer 321 and conductive pads 322, as shown in FIGS. 3A.

The discussion of the structure of FIG. 3A applies to the structure of FIG. 3C, unless mentioned otherwise. Referring to FIG. 3C, in some embodiments, IC chip coupler 108 can be positioned with the back-side of IC chip coupler 108 facing conductive bonding structures 114B, similar to that in FIG. 3A, but IC chip coupler 108 can be electrically connected to conductive bonding structures 114B with one or more back-side conductive pads 322b, instead of conductive through-via 319, as shown in FIG. 3A. Referring to FIG. 3C, in some embodiments, IC chip coupler 108 can further include (i) a back-side interconnect structure 316b disposed on back-side surface 312b of substrate 312, (ii) conductive through-vias 319b disposed in substrate 312 and electrically connected to source/drain regions of FET 352, (iii) back-side passivation layers 320b-321b disposed on back-side interconnect structure 316b, and (iv) back-side conductive pads 322b disposed in back-side passivation layers 320b-321b and on back-side interconnect structure 316b. The one or more back-side conductive pads 322 can electrically connect back-side interconnect structure 316b to conductive bonding structures 114B.

In some embodiments, back-side interconnect structure 316b can include interconnect layers Mb1-Mb3. Though three interconnect layers Mb1-Mb3 are discussed, back-side interconnect structure 316b can have any number of interconnect layers. Each of interconnect layers Mb1-Mb3 can include an etch stop layer (ESL) 338b and an ILD layer 340b. In some embodiments, each of interconnect layers Mb1-Mb3 can further include one or more metal lines 342b and one or more conductive vias 344b. The layout of metal lines 342b and conductive vias 344b is exemplary and not limiting and other layout variations of metal lines 342b and conductive vias 344b are within the scope of this disclosure. In some embodiments, conductive pads 322b, ESLs 338b, ILD 340b, metal lines 342b, and conductive vias 344b can include materials similar to conductive pads 322, ESLs 338, ILD 340, metal lines 342, and conductive vias 344, respectively.

Referring to FIGS. 3D-3E, in some embodiments, IC chip coupler 108 can be a signal routing chip and can include routing structures, such as interconnect structures 316 and/or conductive through-vias 319, but does not include active and/or passive devices. FIG. 3F illustrates a top-down view of IC chip coupler 108 along line G-G of FIG. 3D, according to some embodiments.

The discussion of the structures of FIGS. 3A and 3B applies to the structures of FIGS. 3D and 3E, unless mentioned otherwise. Referring to FIGS. 3D-3E, in some embodiments, IC chip coupler 108 does not include FET 352 and conductive vias 336. Referring to FIG. 3F, in some embodiments, conductive pads 322 can be electrically connected to conductive lines 323, which can include a material similar to that of conductive pads 322. In some embodiments, interconnect structures 316, conductive through-vias 319, conductive pads 322, and/or conductive lines 323 can act as signal propagation paths for transmitting signals between IC chips on different interconnect substrates 104A-1041, as discussed above with reference to FIGS. 1A-1F.

Referring to FIGS. 3G-3H, in some embodiments, IC chip coupler 108 can include one or more circuits with passive devices, such as a decoupling capacitor 350, and routing structures, such as interconnect structures 316 and/or conductive through-vias 319, but may not include active devices, such as FET 352.

The discussion of the structures of FIGS. 3A and 3B applies to the structures of FIGS. 3G and 3H, unless mentioned otherwise. Referring to FIGS. 3G and 3H, in some embodiments, IC chip coupler 108 can include decoupling capacitor 350 disposed in interconnect structure 316 and electrically connected to metal lines 342 and conductive vias 344, but does not include FET 352 and conductive vias 336. In some embodiments, decoupling capacitor 350 can have a metal-insulator-metal (MIM) capacitor structure. Decoupling capacitor 350 can mitigate power line ripple (e.g., current fluctuations) and can provide electromagnetic (EM) shielding for EM emissions from adjacent devices.

In some embodiments, decoupling capacitor 350 can be disposed in ILD layer 340 of one of interconnect lines M1-M5. Decoupling capacitor 350 can have the structure of a parallel plate capacitor and can include a top electrode 353, a bottom electrode 354, and an insulating layer 356 disposed between top electrode 353 and bottom electrode 354. In some embodiments, top electrode 352 can be electrically connected to metal line 342a through conductive via 344a, while bottom electrode 354 can be electrically connected to metal line 342b through conductive via 344b. In some embodiments, metal line 342a-342b can be electrically connected to the same voltage level or to different voltage levels. In some embodiments, top electrode 353 and bottom electrode 354 can include an aluminum copper alloy, tantalum nitride, aluminum, copper, tungsten, metal silicides, or other suitable conductive materials. In some embodiments, a distance D3 between top electrode 353 and metal line 342a can be about 0.1 μm to about 0.7 μm.

Referring to FIG. 31, in some embodiments, IC coupler 108 can include both active devices, such as FET 352, and passive devices, such as decoupling capacitor 350, along with routing structures, such as interconnect structures 316 and/or conductive through-vias 319.

Referring to FIG. 3J, in some embodiments, IC chip coupler 108 can include a photonic circuit 360, and routing structures, such as interconnect structures 316 and/or conductive through-vias 319. In some embodiments, IC chip coupler 108 of FIG. 3J can also include active devices, such as FET 352, and/or passive devices, such as decoupling capacitor 350, which are not shown in FIG. 3J for simplicity. In some embodiments, photonic circuit 360 can include a radiation emitting device 362, a radiation sensing device 364, and a detection circuit 366. In some embodiments, radiation emitting device 362 can include a light emitting diode (LED), a laser diode, an infrared emitting diode, or other suitable semiconductor light sources. In some embodiments, radiation sensing device 364 can include a photodiode, a phototransistor, or a photocell. In some embodiments, detection circuit 366 can convert optical signals from radiation sensing device 364 into electrical signals. In some embodiments, radiation sensing device 364 and detection circuit 366 can be included in IC chip coupler 108, but radiation emitting device 362 can be included in an IC chip (e.g., IC chip 107C) adjacent to IC chip coupler 108, as shown in FIG. 3K.

The above discussion of IC coupler 108, conductive bonding structures 114B, and encapsulating layer 116B in FIGS. 3A-3I applies to IC coupler 208, conductive bonding structures 114D, and encapsulating layer 116D, respectively.

In some embodiments, one or more IC chips 107A-107K can have cross-sectional views similar to the cross-sectional views of IC chip coupler 108 shown in FIGS. 3A-3C and 3I-3K.

FIG. 4A illustrates an isometric view of FET 352 in device layer 314 and metal line layer M1 of front-side interconnect structure 316 in region 301 of FIG. 3A, according to some embodiments. FIGS. 4B-4C illustrate different cross-sectional views along line H-H of FIG. 3A with additional structures that are not shown in FIG. 3A for simplicity, according to some embodiments. The discussion of elements in FIGS. 3A-3C, 3I, and 4A-4C with the same annotations applies to each other, unless mentioned otherwise. The elements of front-side interconnect structure 316 are not shown in FIG. 4A for simplicity. In some embodiments, FET 352 can represent n-type FET 352 (NFET 352) or p-type FET 352 (PFET 352) and the discussion of FET 352 applies to both NFET 352 and PFET 352, unless mentioned otherwise. In some embodiments, FET 352 can be formed on substrate 312 and can include an array of gate structures 412 disposed on a fin structure 406 and an array of S/D regions 410A-410C (S/D region 410A visible in FIG. 4A; 410A-410C visible in FIGS. 4B-4C) disposed on portions of fin structure 106 that are not covered by gate structures 412. In some embodiments, fin structure 406 can include a material similar to substrate 312 and extend along an X-axis. In some embodiments, FET 352 can further include gate spacers 414, STI regions 416, ESLs 417A-417C, and ILD layers 418A-418C. In some embodiments, gate spacers 414, STI regions 416, ESLs 417A, and ILD layers 418A-418B can include an insulating material, such as silicon oxide, silicon nitride (SiN), silicon carbon nitride (SiCN), silicon oxycarbon nitride (SiOCN), and silicon germanium oxide.

Referring to FIG. 4B, in some embodiments, FET 352 can be a GAA FET 352 and can include (i) S/D regions 410A-410C, (ii) contact structures 430 disposed on front-side surface of S/D regions 410A-410C, (iii) via structures 336 disposed on contact structures 430, (iv) nanostructured channel regions 420 disposed on fin structure 406, and (v) gate structures 412 surrounding nanostructured channel regions 420. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, or about 10 nm; other values less than about 100 nm are within the scope of the disclosure. In some embodiments, FET 352 can be a finFET 352, as shown in FIG. 4C.

In some embodiments, nanostructured channel regions 420 can include semiconductor materials similar to or different from substrate 312. In some embodiments, nanostructured channel regions 420 can include Si, SiAs, silicon phosphide (SiP), SiC, SiCP, SiGe, silicon germanium boron (SiGeB), germanium boron (GeB), silicon germanium stannum boron (SiGeSnB), a III-V semiconductor compound, or other suitable semiconductor materials. Though rectangular cross-sections of nanostructured channel regions 420 are shown, nanostructured channel regions 420 can have cross-sections with other geometric shapes (e.g., circular, elliptical, triangular, or polygonal). Gate portions of gate structures 412 surrounding nanostructured channel regions 420 can be electrically isolated from adjacent S/D regions 410A-410C by inner spacers 413. Inner spacers 413 can include an insulating material, such as SiOₓ, SiN, SiCN, SiOCN, and other suitable insulating materials.

Each of gate structures 412 can include (i) an interfacial oxide (IO) layer 422, (ii) a high-k (HK) gate dielectric layer 424 disposed on IO layer 422, (iii) a work function metal (WFM) layer 426 disposed on HK gate dielectric layer 424, and (iv) a gate metal fill layer 428 disposed on WFM layer 426. IO layers 422 can include silicon oxide (SiO₂), silicon germanium oxide (SiGeOₓ), germanium oxide (GeOₓ), or other suitable oxide materials. HK gate dielectric layers 424 can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), zirconium silicate (ZrSiO₂), and other suitable high-k dielectric materials.

For NFET 352, WFM layer 426 can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, other suitable Al-based conductive materials, or a combination thereof. For PFET 352, WFM layer 426 can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, tantalum copper (Ta—Cu), other suitable substantially Al-free conductive materials, or a combination thereof. Gate metal fill layers 428 can include a conductive material, such as tungsten (W), Ti, silver (Ag), ruthenium (Ru), molybdenum (Mo), copper (Cu), cobalt (Co), Al, iridium (Ir), nickel (Ni), metal alloys, other suitable conductive materials, and a combination thereof.

For NFET 352, each of S/D regions 410A-410C can include an epitaxially-grown semiconductor material, such as Si, and n-type dopants, such as phosphorus and other suitable n-type dopants. For PFET 352, each of S/D regions 410A-410C can include an epitaxially-grown semiconductor material, such as Si and SiGe, and p-type dopants, such as boron and other suitable p-type dopants. In some embodiments, each of contact structures 430 can include (i) a silicide layer 432 disposed within each of S/D regions 410A-410C and (ii) a contact plug 434 disposed on silicide layer 432. In some embodiments, silicide layers 432 can include a metal silicide. In some embodiments, contact plugs 434 can include a conductive material, such as cobalt (Co), tungsten (W), ruthenium (Ru), iridium (Ir), nickel (Ni), osmium (Os), rhodium (Rh), aluminum (Al), molybdenum (Mo), other suitable conductive materials, and a combination thereof. In some embodiments, via structures 336 can include conductive materials, such as Ru, Co, Ni, Al, Mo, W, Ir, Os, Cu, and Pt. Contact structures 430 can electrically connect to overlying metal lines 344 through via structures 336.

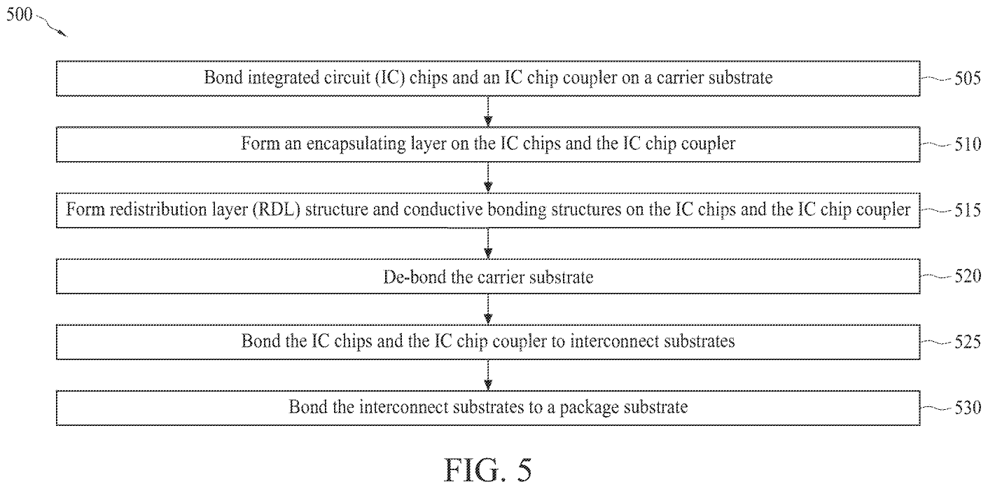

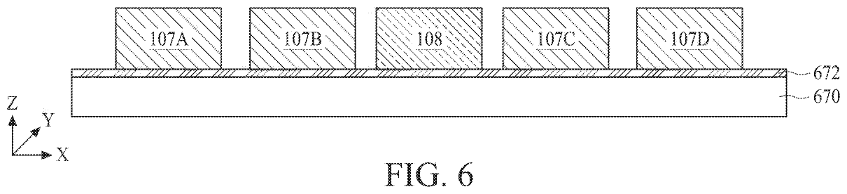

FIG. 5 is a flow diagram of an example method 500 for fabricating IC chip package 100 with cross-sectional view shown in FIG. 1A, according to some embodiments. For illustrative purposes, the operations illustrated in FIG. 5 will be described with reference to the example fabrication process for fabricating IC chip package 100 as illustrated in FIGS. 6-13. FIGS. 6-13 are cross-sectional views of IC chip package 100 at various stages of fabrication, according to some embodiments. Operations can be performed in a different order or not performed depending on specific applications. It should be noted that method 500 may not produce a complete IC chip package 100. Accordingly, it is understood that additional processes can be provided before, during, and after method 500, and that some other processes may only be briefly described herein. Elements in FIGS. 6-13 with the same annotations as elements in FIGS. 1A-1F and 3A-3K are described above.

Referring to FIG. 5, in operation 505, IC chips and an IC chip coupler are bonded to a carrier substrate. For example, as shown in FIG. 6, IC chips 107A-107D and IC chip coupler 108 are bonded to a carrier substrate 670 with a de-bonding layer 672.

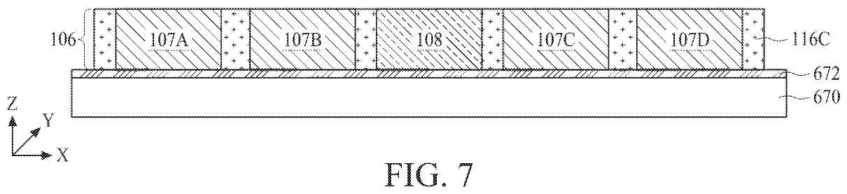

Referring to FIG. 5, in operation 510, an encapsulating layer is formed on the IC chips and the IC chip coupler. For example, as shown in FIG. 7, encapsulating layer 116C is formed on IC chips 107A-107D and IC chip coupler 108. The formation of encapsulating layer 116C includes depositing an encapsulating material on the structure of FIG. 6 and performing a chemical mechanical polishing (CMP) process on the encapsulating material to form the structure of FIG. 7.

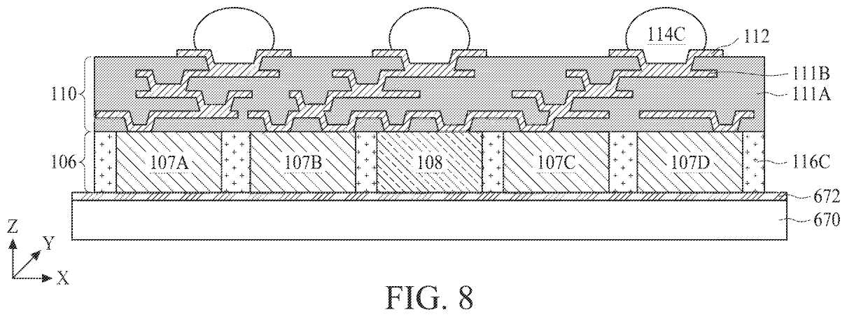

Referring to FIG. 5, in operation 515, an RDL structure and conductive bonding structures are formed on the IC chips and the IC chip coupler. For example, as shown in FIG. 8, RDL structure 110 and conductive bonding structures 114C are formed on IC chips 107A-107D and IC chip coupler 108.

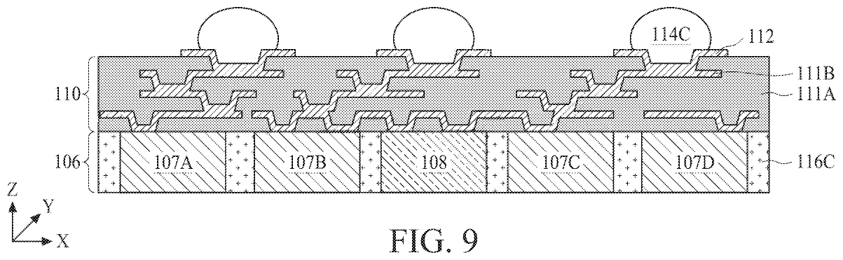

Referring to FIG. 5, in operation 520, the carrier substrate is de-bonded. For example, as shown in FIG. 9, carrier substrate 670 is de-bonded from IC chips 107A-107D and IC chip coupler 108. The de-bonding process can include projecting a UV light or a laser on de-bonding layer 672 to decompose the material of de-bonding layer 672 and detach carrier substrate 670 from IC chips 107A-107D and IC chip coupler 108.

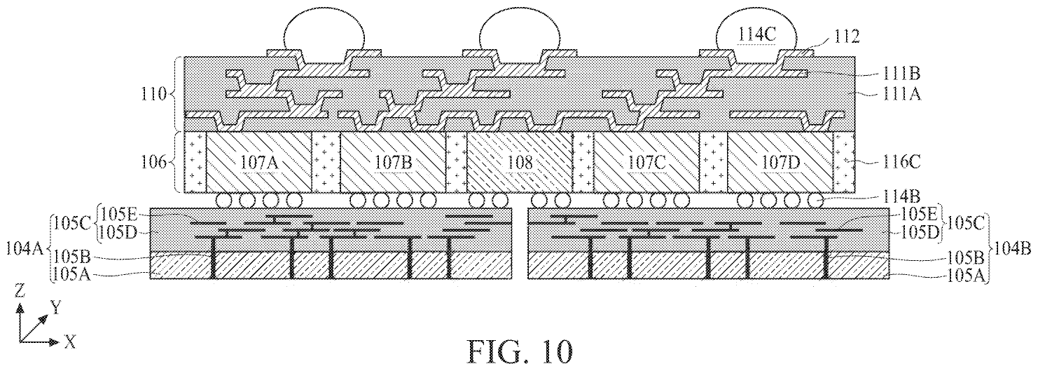

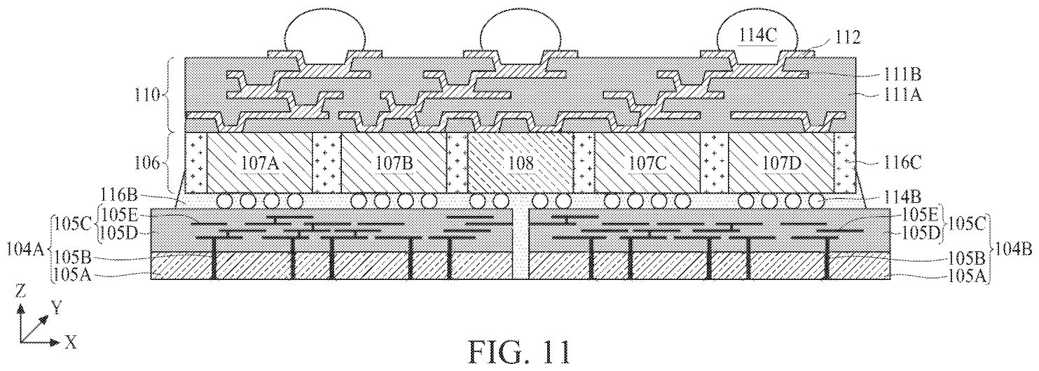

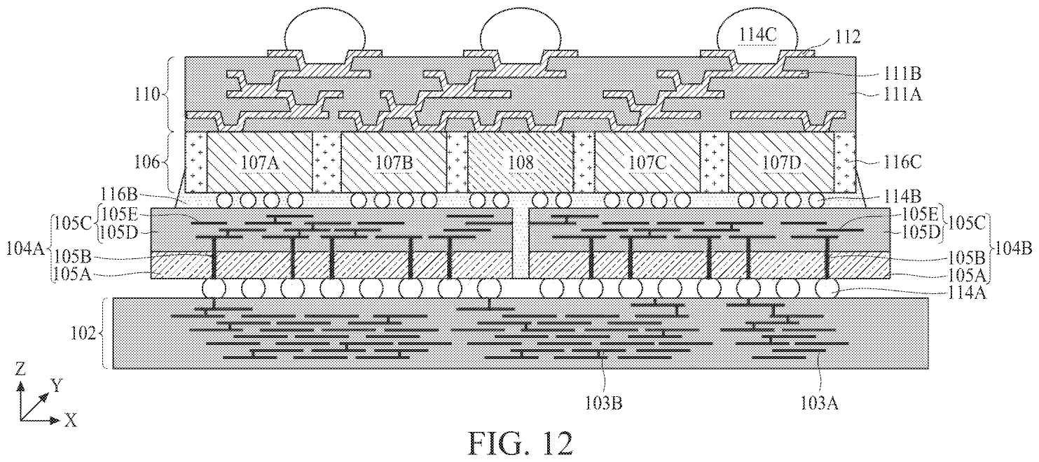

Referring to FIG. 5, in operation 525, the IC chips and the IC chip coupler are bonded to interconnect substrates. For example, as shown in FIG. 10, IC chips 107A-107B are bonded to interconnect substrate 104A, IC chips 107C-107D are bonded to interconnect substrate 104B, and IC chip coupler 108 is bonded to interconnect substrates 104A-104B with conductive bonding structures 114B. In some embodiments, conductive bonding structures 114B can include copper pillars or micro solder bumps. The bonding process can be followed by a gap filling process to fill the gaps between interconnect substrates 104A-104B and IC chips 107A-107D and IC chip coupler 108 with encapsulating layer 116B, as shown in FIG. 11.

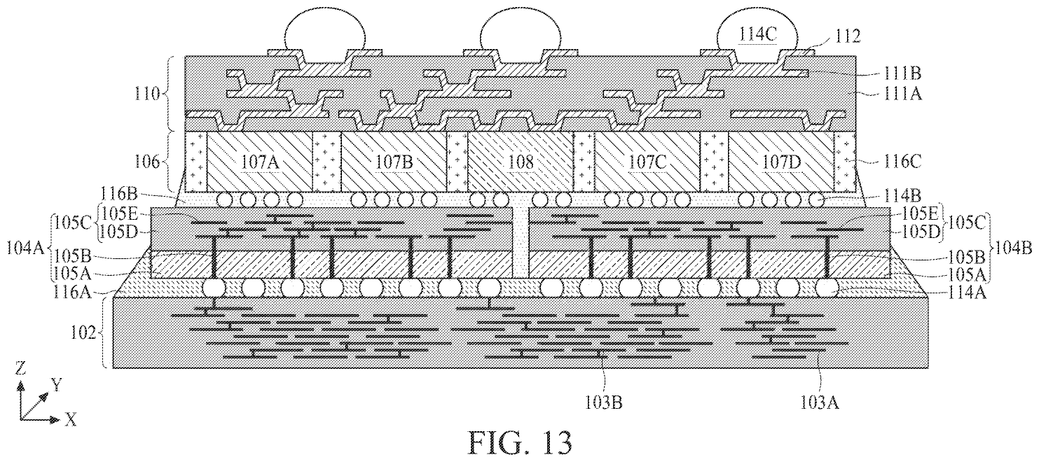

Referring to FIG. 5, in operation 530, the interconnect substrates are bonded to a package substrate. For example, as shown in FIG. 12, interconnect substrates 104A-104B are bonded to package substrate 102 with conductive bonding structures 114A. In some embodiments, conductive bonding structures 114A can include copper or solder bumps. The bonding process can be followed by a gap filling process to fill the gaps between package substrate 102 and interconnect substrates 104A-104B with encapsulating layer 116A, as shown in FIG. 13.

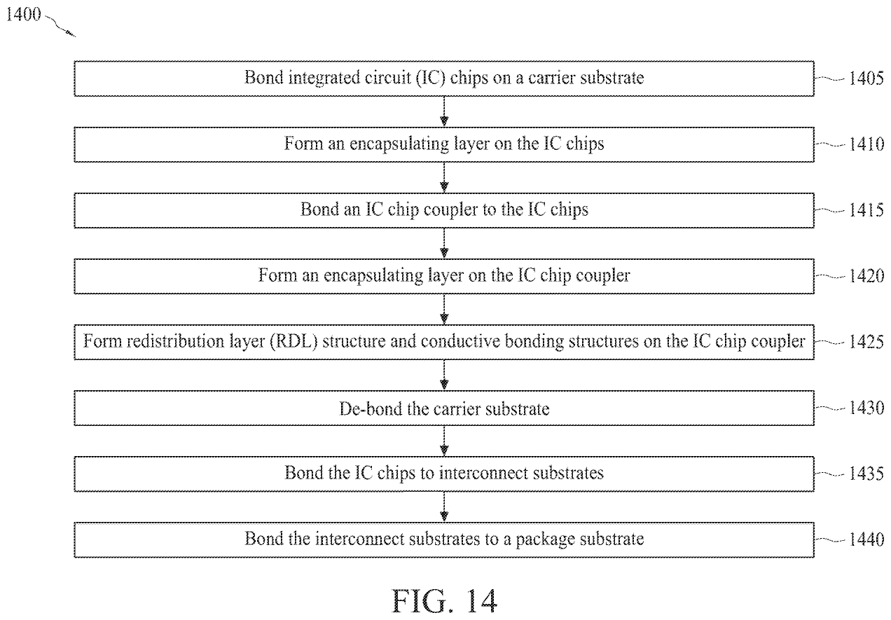

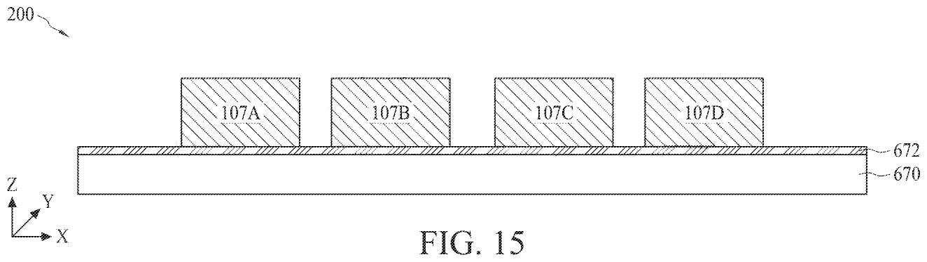

FIG. 14 is a flow diagram of an example method 1400 for fabricating IC chip package 200 with cross-sectional view shown in FIG. 2A, according to some embodiments. For illustrative purposes, the operations illustrated in FIG. 14 will be described with reference to the example fabrication process for fabricating IC chip package 200 as illustrated in FIGS. 15-24. FIGS. 15-24 are cross-sectional views of IC chip package 200 at various stages of fabrication, according to some embodiments. Operations can be performed in a different order or not performed depending on specific applications. It should be noted that method 1400 may not produce a complete IC chip package 200. Accordingly, it is understood that additional processes can be provided before, during, and after method 1400, and that some other processes may only be briefly described herein. Elements in FIGS. 15-24 with the same annotations as elements in FIGS. 1A-1F, 2A-2F, 3A-3K, and 6-13 are described above.

Referring to FIG. 14, in operation 1405, IC chips are bonded to a carrier substrate. For example, as shown in FIG. 15, IC chips 107A-107D are bonded to carrier substrate 670 with de-bonding layer 672.

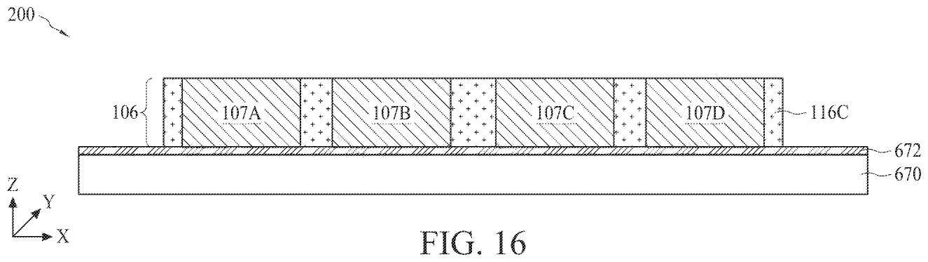

Referring to FIG. 14, in operation 1410, an encapsulating layer is formed on the IC chips. For example, as shown in FIG. 16, encapsulating layer 116C is formed on IC chips 107A-107D. The formation of encapsulating layer 116C includes depositing an encapsulating material on the structure of FIG. 15, and performing a CMP process on the encapsulating material to form the structure of FIG. 16.

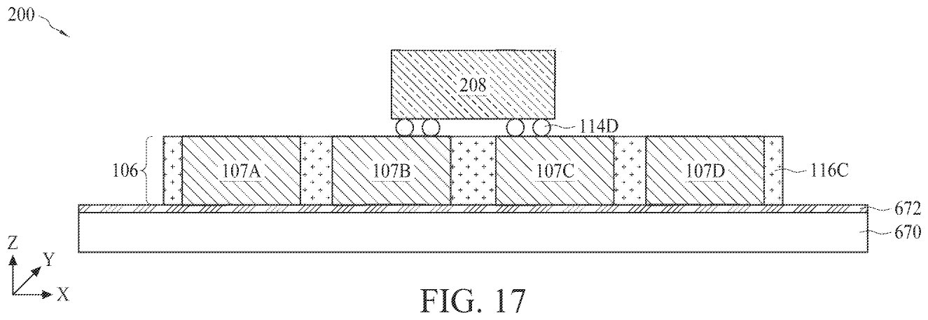

Referring to FIG. 14, in operation 1415, an IC chip coupler is bonded to the IC chips. For example, as shown in FIG. 17, IC chip coupler 208 is bonded to IC chips 107B-107C with conductive bonding structures 114D. In some embodiments, conductive bonding structures 114D can include copper pillars or micro solder bumps.

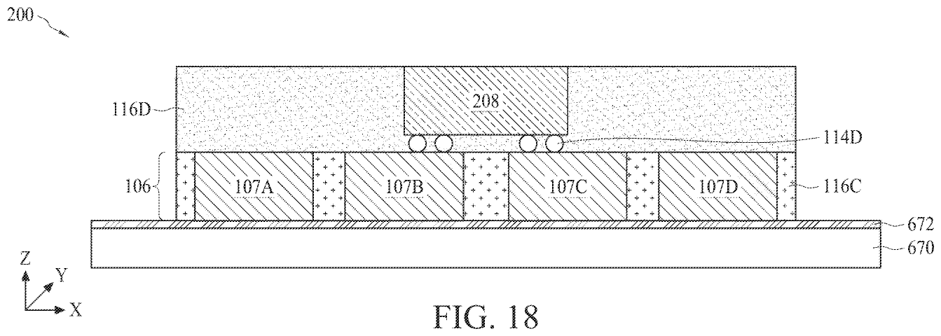

Referring to FIG. 14, in operation 1420, an encapsulating layer is formed on the IC chip coupler. For example, as shown in FIG. 18, encapsulating layer 116D is formed on IC chip coupler 208 to surround IC chip coupler 208 and fill the gaps between conductive bonding structures 114D. The formation of encapsulating layer 116D includes depositing an encapsulating material on the structure of FIG. 17 and performing a CMP process on the encapsulating material to form the structure of FIG. 18.

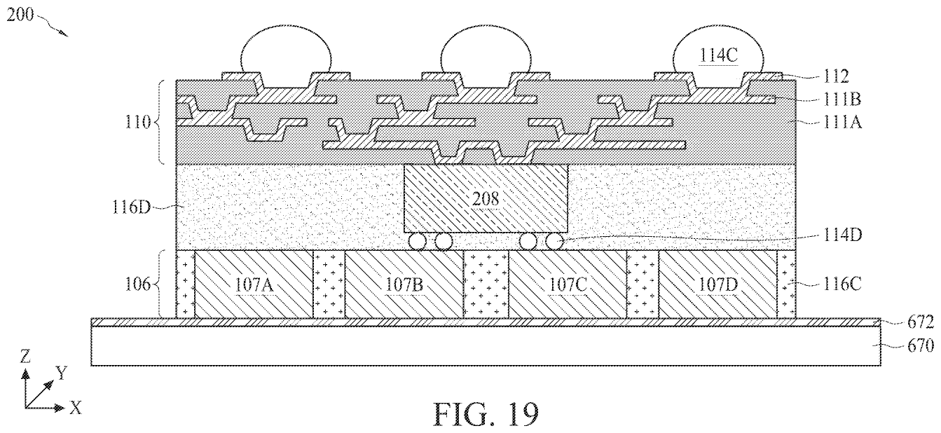

Referring to FIG. 14, in operation 1425, an RDL structure and conductive bonding structures are formed on the IC chip coupler. For example, as shown in FIG. 19, RDL structure 110 and conductive bonding structures 114C are formed on IC chip coupler 208.

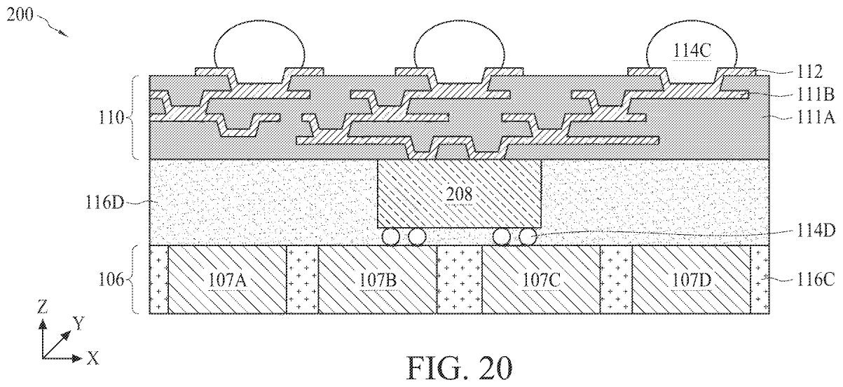

Referring to FIG. 14, in operation 1430, the carrier substrate is de-bonded. For example, as shown in FIG. 20, carrier substrate 670 is de-bonded from IC chips 107A-107D. The de-bonding process can include projecting a UV light or a laser on de-bonding layer 672 to decompose the material of de-bonding layer 672 and detach carrier substrate 670 from IC chips 107A-107D.

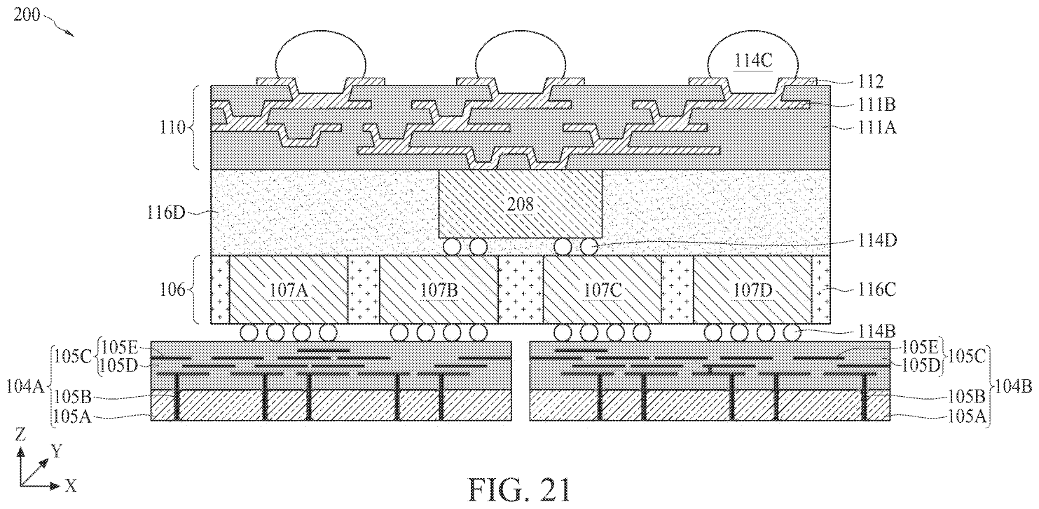

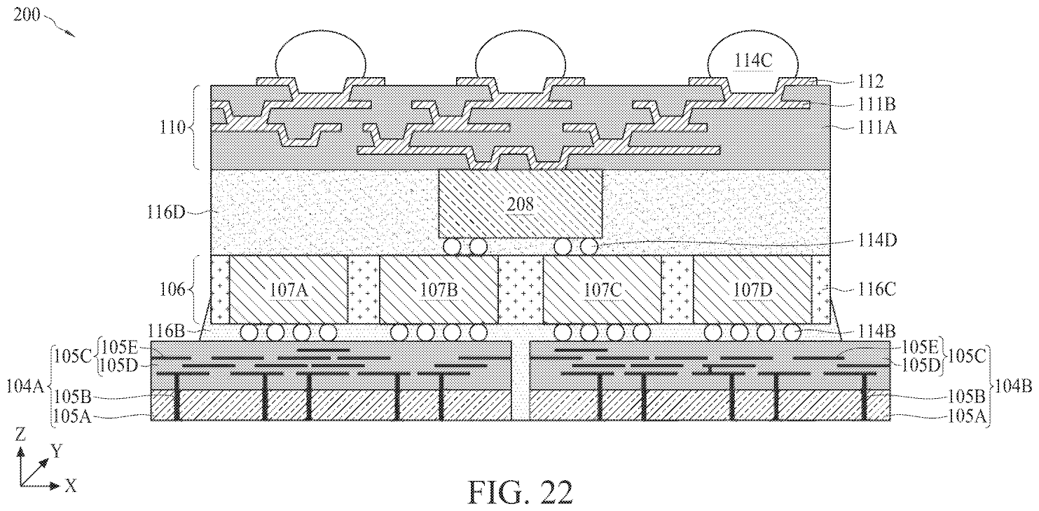

Referring to FIG. 14, in operation 1435, the IC chips are bonded to interconnect substrates. For example, as shown in FIG. 21, IC chips 107A-107B are bonded to interconnect substrate 104A and IC chips 107C-107D are bonded to interconnect substrate 104B with conductive bonding structures 114B. In some embodiments, conductive bonding structures 114B can include copper pillars or micro solder bumps. The bonding process can be followed by a gap filling process to fill the gaps between interconnect substrates 104A-104B and IC chips 107A-107D with encapsulating layer 116B, as shown in FIG. 22.

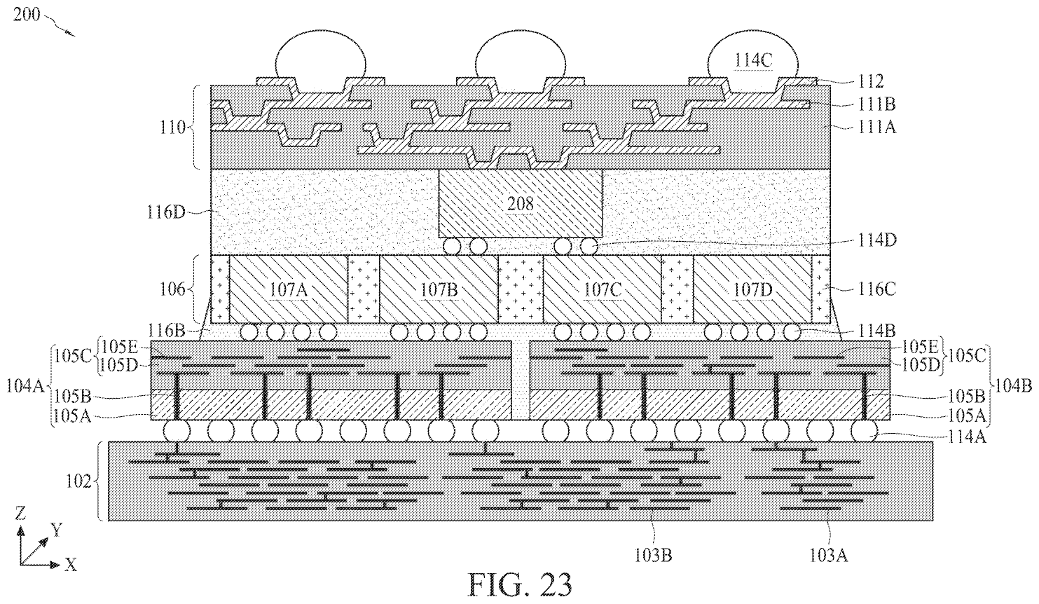

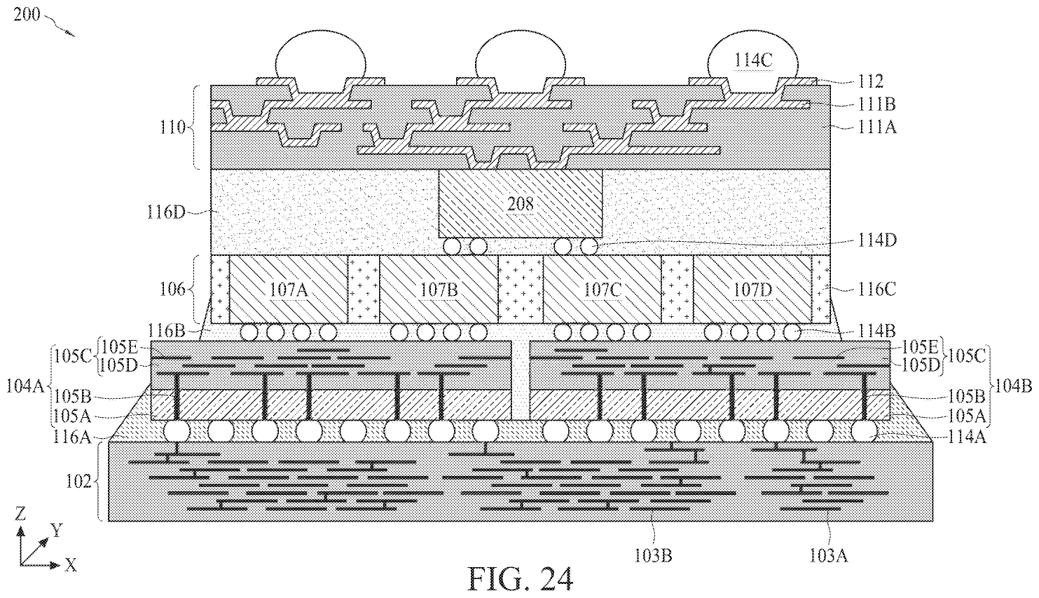

Referring to FIG. 14, in operation 1440, the interconnect substrates are bonded to a package substrate. For example, as shown in FIG. 23, interconnect substrates 104A-104B are bonded to package substrate 102 with conductive bonding structures 114A. In some embodiments, conductive bonding structures 114A can include copper or solder bumps. The bonding process can be followed by a gap filling process to fill the gaps between package substrate 102 and interconnect substrates 104A-104B with encapsulating layer 116A, as shown in FIG. 24.

The present disclosure provides example structures of IC chip packages (e.g., IC chip packages 100 and 200) with IC chip couplers (e.g., IC chip couplers 108 and 208) and example methods (e.g., methods 500 and 1400) of fabricating the same to reduce the signal transmission path lengths (e.g., paths 109A-109B) between the IC chips (e.g., IC chips 107A-107D) on different interconnect substrates (e.g., interconnect substrates 104A-104B). In some embodiments, an IC chip coupler can be disposed on and electrically connected to two or more interconnect structures and can electrically connect the IC chips on different interconnect substrates. In some embodiments, electrical signals between the IC chips (e.g., IC chips 107C and 107D) on different interconnect substrates (e.g., interconnect substrates 104A-104B) can be transmitted through the IC chip coupler (e.g., IC chip coupler 108) and the different interconnect substrates without passing through the package substrate (e.g., package substrate 102). As a result, the signal transmission path lengths between the IC chips on different interconnect substrates can be reduced (e.g., paths 109A-109B), thus decreasing the signal transmission path resistance and increasing the signal transmission speed and bandwidth of the IC chip package.

In some embodiments, a structure includes first and second interconnect substrates on a same surface level, first and second integrated circuit (IC) chips disposed on the first and second interconnect substrates, respectively, an IC chip coupler disposed on the first and second interconnect substrates and configured to provide a signal transmission path between the first and second IC chips, and a redistribution structure disposed on the first and second IC chips and the IC chip coupler. The IC chip coupler includes a first coupler region that overlaps with the first interconnect substrate, a second coupler region that overlaps with the second interconnect substrate, a third coupler region that overlaps with a space between the first and second interconnect substrates, and an interconnect structure with conductive lines and conductive vias.

In some embodiments, a structure includes a structure includes first and second interconnect substrates on a same surface level, first and second integrated circuit (IC) chips disposed on the first and second interconnect substrates, respectively, an IC chip coupler disposed on the first and second IC chips and configured to provide a signal transmission path between the first and second IC chips, and a redistribution structure disposed on the IC chip coupler. The IC chip coupler includes a first coupler region that overlaps with the first IC chip, a second coupler region that overlaps with the second IC chip, a third coupler region that overlaps with a space between the first and second IC chips, and an interconnect structure with conductive lines and conductive vias.

In some embodiments, a method includes bonding first and second integrated circuit (IC) chips and an IC chip coupler on a carrier substrate, forming an encapsulating layer on the first and second IC chips and the IC chip coupler, removing the carrier substrate, bonding the first IC chip to a first interconnect substrate, bonding the second IC chip to a second interconnect substrate, bonding the IC chip coupler to the first and second interconnect substrates, and bonding the first and second interconnect substrates to a package substrate.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A structure, comprising:
first and second interconnect substrates on a same surface level;
first and second integrated circuit (IC) chips disposed on the first and second interconnect substrates, respectively;
an IC chip coupler disposed on the first and second interconnect substrates and configured to provide a signal transmission path between the first and second IC chips, wherein the IC chip coupler comprises:
a first coupler region that overlaps with the first interconnect substrate,
a second coupler region that overlaps with the second interconnect substrate,
a third coupler region that overlaps with a space between the first and second interconnect substrates, and
an interconnect structure with conductive lines and conductive vias; and
a redistribution structure disposed on the first and second IC chips and the IC chip coupler.

2. The structure of claim 1, wherein vertical dimensions of the first and second IC chips and the IC chip coupler are substantially equal.

3. The structure of claim 1, wherein top surfaces of the first and second IC chips and the IC chip coupler are substantially coplanar.

4. The structure of claim 1, wherein surface areas of the first and second coupler regions are substantially equal to each other.

5. The structure of claim 1, wherein a total surface area of the first and second coupler regions is equal to or greater than about 50% of a surface area of the third coupler region.

6. The structure of claim 1, wherein a total surface area of the first and second coupler regions is equal to or greater than about 20% of a total surface area of the IC chip coupler.

7. The structure of claim 1, wherein a surface area of each of the first and second coupler regions is greater than about 5% of a total surface area of the first and second coupler regions.

8. The structure of claim 1, wherein a surface area of the first coupler region is equal to or greater than about 10% of a surface area of the second coupler region.

9. The structure of claim 1, wherein a difference between surface areas of the first and second coupler regions is equal to or less than about 80% of a total surface area of the first and second coupler regions.

10. The structure of claim 1, wherein a smallest horizontal dimension of each of the first and second coupler regions is greater than about 10 μm.

11. The structure of claim 1, further comprising third and fourth interconnect substrates disposed on the same surface level as the first and second interconnect substrates, wherein the IC chip coupler further comprises fourth and fifth coupler regions that overlap with the third and fourth interconnect substrates, respectively.

12. The structure of claim 1, wherein the IC chip coupler further comprises an active device layer electrically connected to the interconnect structure.

13. The structure of claim 1, wherein the IC chip coupler further comprises a decoupling capacitor electrically connected to the interconnect structure.

14. A structure, comprising:
first and second interconnect substrates on a same surface level;
first and second integrated circuit (IC) chips disposed on the first and second interconnect substrates, respectively;
an IC chip coupler disposed on the first and second IC chips and configured to provide a signal transmission path between the first and second IC chips, wherein the IC chip coupler comprises:
a first coupler region that overlaps with the first IC chip,
a second coupler region that overlaps with the second IC chip,
a third coupler region that overlaps with a space between the first and second IC chips, and
an interconnect structure with conductive lines and conductive vias; and
a redistribution structure disposed on the IC chip coupler.

15. The structure of claim 14, wherein a total surface area of the first and second coupler regions is equal to or greater than about 50% of a surface area of the third coupler region

16. The structure of claim 14, wherein a total surface area of the first and second coupler regions is equal to or greater than about 20% of a total surface area of the IC chip coupler.

17. The structure of claim 14, wherein a surface area of the first coupler region is equal to or greater than about 10% of a surface area of the second coupler region.

18. A method, comprising:
bonding first and second integrated circuit (IC) chips and an IC chip coupler on a carrier substrate;
forming an encapsulating layer on the first and second IC chips and the IC chip coupler;
removing the carrier substrate;
bonding the first IC chip to a first interconnect substrate;
bonding the second IC chip to a second interconnect substrate;
bonding the IC chip coupler to the first and second interconnect substrates; and
bonding the first and second interconnect substrates to a package substrate.

19. The method of claim 18, further comprising forming a redistribution structure on the first and second IC chips and the IC chip coupler prior to removing the carrier substrate.

20. The method of claim 18, further comprising forming an encapsulation layer between the IC chip coupler and the first and second interconnect substrates.
